(19) United States
(12) Patent Application Publication
(10) Pub. No.: US 2025/0267954 A1
(43) Pub. Date: Aug. 21, 2025

(54) SEMICONDUCTOR DEVICE

(71) Applicant: ROHM CO., LTD., Kyoto (JP)

(72) Inventors: Kohei MORITA, Kyoto (JP); Satoki TANIGUCHI, Kyoto (JP); Kentaro NASU, Kyoto (JP); Keishi WATANABE, Kyoto (JP); Kentaro WAKI, Kyoto (JP)

(73) Assignee: ROHM CO., LTD., Kyoto (JP)

(21) Appl. No.: 19/053,863

(22) Filed: Feb. 14, 2025

(30) Foreign Application Priority Data
Feb. 19, 2024 (JP) 2024-023101

(51) Int. Cl. H10D 89/60; H01L 23/00

(52) U.S. Cl. CPC H10D 89/611; H01L 24/05; H01L 2224/04042; H01L 2224/05082

(57) ABSTRACT

A semiconductor device includes: a semiconductor layer of a first conductivity type having a main surface; a first diffusion region of a second conductivity type formed in a surface layer portion of the main surface; a second diffusion region of the first conductivity type formed in the surface layer portion of the main surface; an insulating layer formed on the main surface so as to cover the first diffusion region and the second diffusion region; a first pad disposed on the insulating layer and electrically connected to the first diffusion region; and an internal parasitic capacitance formation portion formed in a surface layer portion of the semiconductor layer and forming an internal parasitic capacitance between a facing portion in the semiconductor layer that faces the first pad with the insulating layer interposed therebetween and the main surface or an extended surface flush with the main surface.

### CROSS-REFERENCE TO RELATED APPLICATION

This application is based upon and claims the benefit of priority from Japanese Patent Application No. 2024-023101, filed on Feb. 19, 2024, the entire contents of which are incorporated herein by reference.

### TECHNICAL FIELD

The present disclosure relates to a semiconductor device.

### BACKGROUND

In the related art, a semiconductor device including a semiconductor substrate and a transient voltage suppressor (TVS) circuit formed on the semiconductor substrate is disclosed. The TVS circuit is constituted by a plurality of diodes including a Zener diode.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is a cross-sectional view taken along line II-II shown in FIG. 1.

FIG. 3 is a cross-sectional view taken along line III-III shown in FIG. 1.

FIG. 4 is a plan view showing a layout of a first pad and a second pad.

FIG. 5 is a plan view showing a layout of a first wiring layer.

FIG. 6 is a plan view showing a layout of a chip.

FIG. 7 is an enlarged view of a portion surrounded by dashed line VII in FIG. 6.

FIG. 8A is a cross-sectional view taken along line VIIIA-VIIIA shown in FIG. 7.

FIG. 8B is an enlarged view of a portion surrounded by dashed line VIIIB in FIG. 8A.

FIG. 9 is a cross-sectional view taken along line IX-IX shown in FIG. 6.

FIG. 10 is an enlarged view of a portion surrounded by dashed line X in FIG. 9.

FIG. 11 is an electric circuit diagram of the semiconductor device.

FIG. 12 is an electric circuit diagram showing a parasitic capacitance around a first pad.

FIG. 13 is a schematic plan view of a diode chip included in a semiconductor device according to a second embodiment of the present disclosure, and corresponds to FIG. 6.

FIG. 14 is a cross-sectional view taken along line XIV-XIV shown in FIG. 13.

FIG. 15 is an enlarged view of a portion surrounded by dashed line XV in FIG. 14.

FIG. 16 is a schematic plan view of a diode chip included in a semiconductor device according to a third embodiment of the present disclosure, and corresponds to FIG. 6.

FIG. 17 is a cross-sectional view taken along line XVII-XVII shown in FIG. 16.

FIG. 18 is an enlarged view of a portion surrounded by dashed line XVIII in FIG. 17.

FIG. 19 is a schematic plan view of a diode chip included in a semiconductor device according to a fourth embodiment of the present disclosure, and corresponds to FIG. 6.

FIG. 20A is a cross-sectional view taken along line XX-XX shown in FIG. 19.

FIG. 20B is a cross-sectional view taken along line XX-XX shown in FIG. 19.

FIG. 21 is an electric circuit diagram showing a parasitic capacitance around a first pad according to the fourth embodiment of the present disclosure.

FIG. 22 is a schematic plan view of a chip included in a semiconductor device according to a fifth embodiment of the present disclosure, and corresponds to FIG. 6.

FIG. 23 is a cross-sectional view taken along line XXIII-XXIII shown in FIG. 22.

FIG. 24 is an electric circuit diagram showing a parasitic capacitance around a first pad according to the fifth embodiment of the present disclosure.

FIG. 25 is a schematic cross-sectional view of a semiconductor device according to a modification (first modification) of the first embodiment of the present disclosure, and corresponds to FIG. 10.

FIG. 26 is an electric circuit diagram showing a parasitic capacitance around a first pad according to the first modification.

FIG. 27 is a schematic cross-sectional view of a semiconductor device according to a modification (second modification) of the first embodiment of the present disclosure, and corresponds to FIG. 9.

FIG. 28 is a schematic cross-sectional view of a semiconductor device according to a modification (third modification) of the second embodiment of the present disclosure, and corresponds to FIG. 15.

FIG. 29 is a schematic cross-sectional view of a semiconductor device according to a modification (fourth modification) of the second embodiment of the present disclosure, and corresponds to FIG. 15.

FIG. 30 is a schematic cross-sectional view of a semiconductor device according to a modification (fifth modification) of the second embodiment of the present disclosure, and corresponds to FIG. 14.

FIG. 31 is a schematic cross-sectional view of a semiconductor device according to a modification (sixth modification) of the fifth embodiment of the present disclosure, and corresponds to FIG. 23.

FIG. 32 is a schematic cross-sectional view of a semiconductor device according to a modification (seventh modification) of the fifth embodiment of the present disclosure, and corresponds to FIG. 23.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, some embodiments of the present disclosure will be described in detail with reference to the accompanying drawings.

The accompanying drawings are all schematic diagrams and are not strictly illustrated, and scales, ratios, angles, etc. are not necessarily the same. Among the accompanying drawings, corresponding structures are denoted by the same reference numerals, and duplicate explanations thereof are omitted or simplified. The descriptions given before the omissions or simplifications apply for structures whose explanations are omitted or simplified.

When the expression “substantially” is used in the present disclosure, this expression includes not only a numerical value (form) which is almost equal to a numerical value (form) to be compared, but also a numerical error (form error) within a range of ±10% based on a numerical value (form) to be compared. Words such as “first,” “second,” and “third” are used in the following description, but these are symbols attached to names of the respective structures to clarify an order of explanation, and are not attached to limit the names of the respective structures.

In the following description, a conductivity type of a semiconductor (impurity) is indicated by using “p-type” or “n-type,” but “p-type” may also be called “first conductivity type” and “n-type” may also be called “second conductivity type.” Of course, “n-type” may also be called “first conductivity type” and “p-type” may also be called “second conductivity type.” The “n-type” is a conductivity type caused by a pentavalent element, and “p-type” is a conductivity type caused by a trivalent element. Unless otherwise specified, the trivalent element is at least one of boron, aluminum, gallium, or indium. Unless otherwise specified, the pentavalent element is at least one of nitrogen, phosphorus, arsenic, antimony, or bismuth.

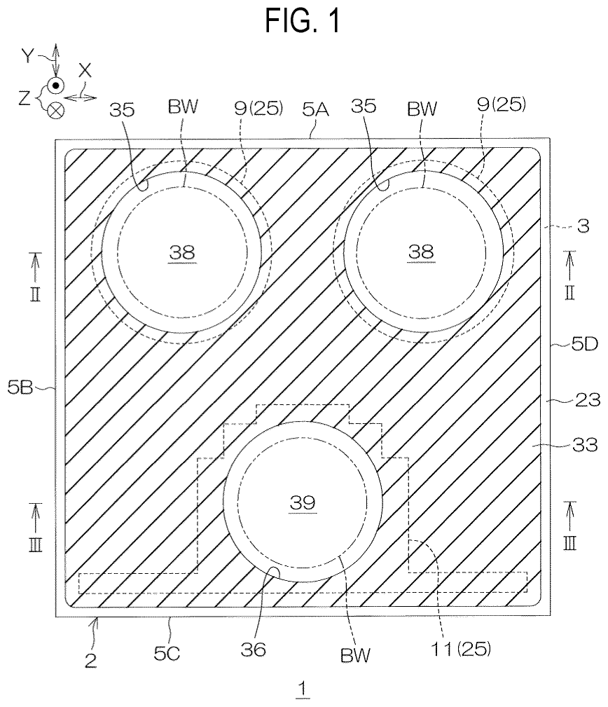

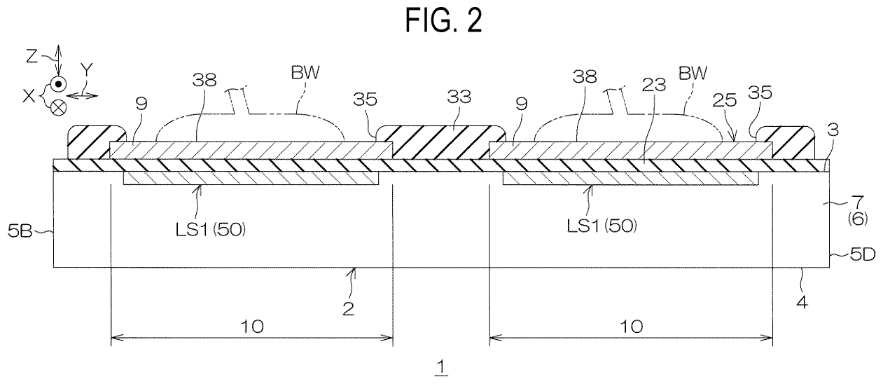

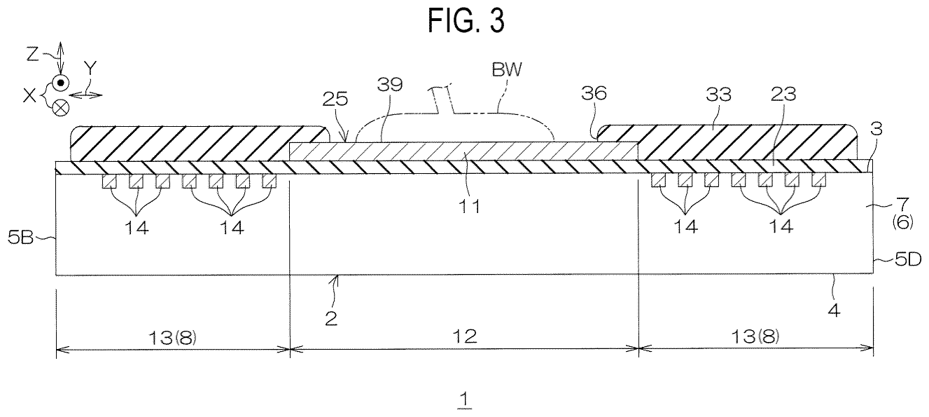

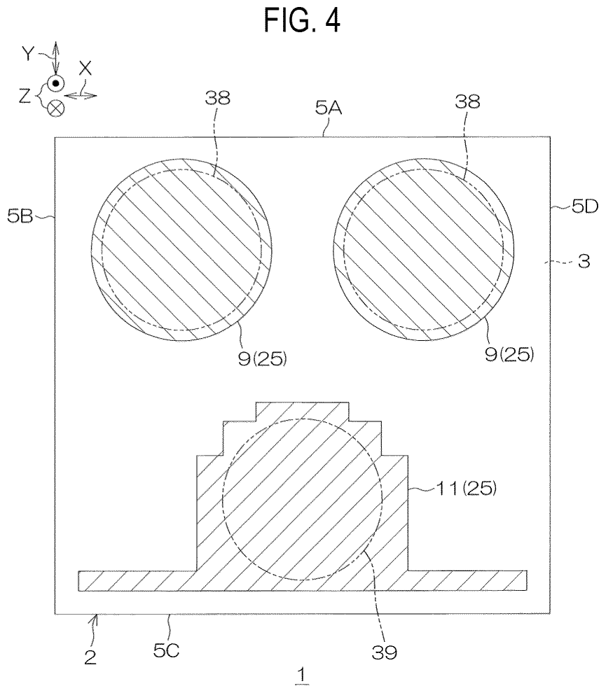

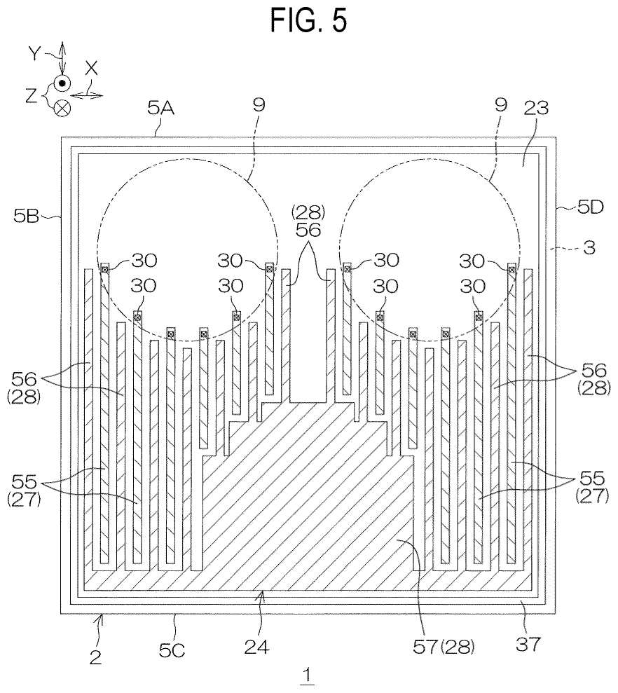

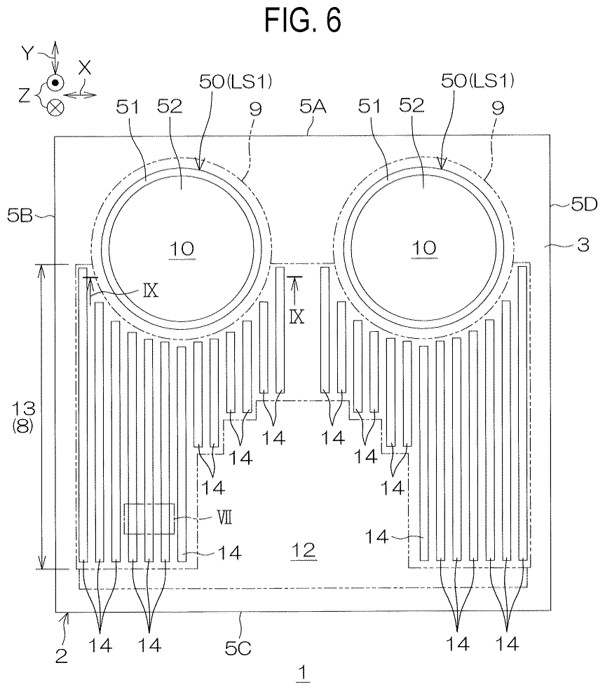

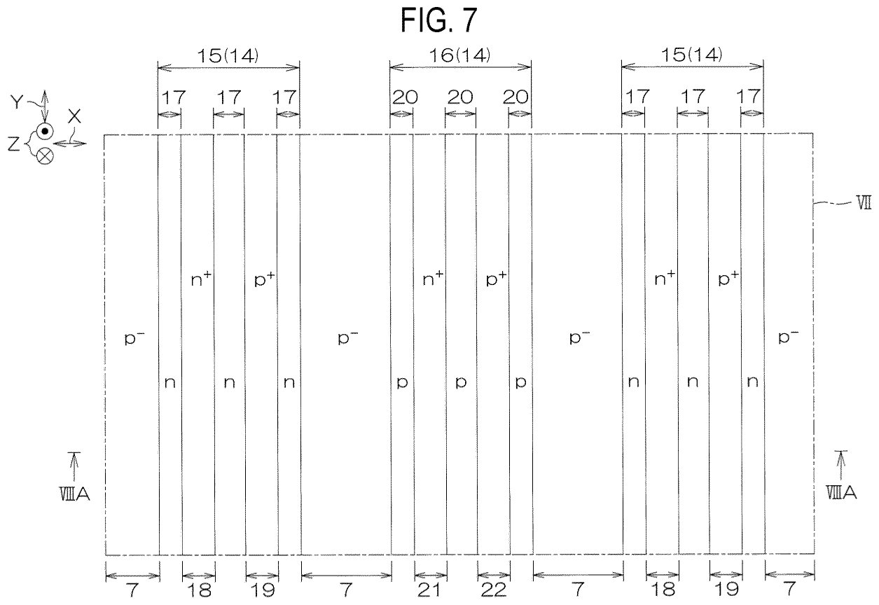

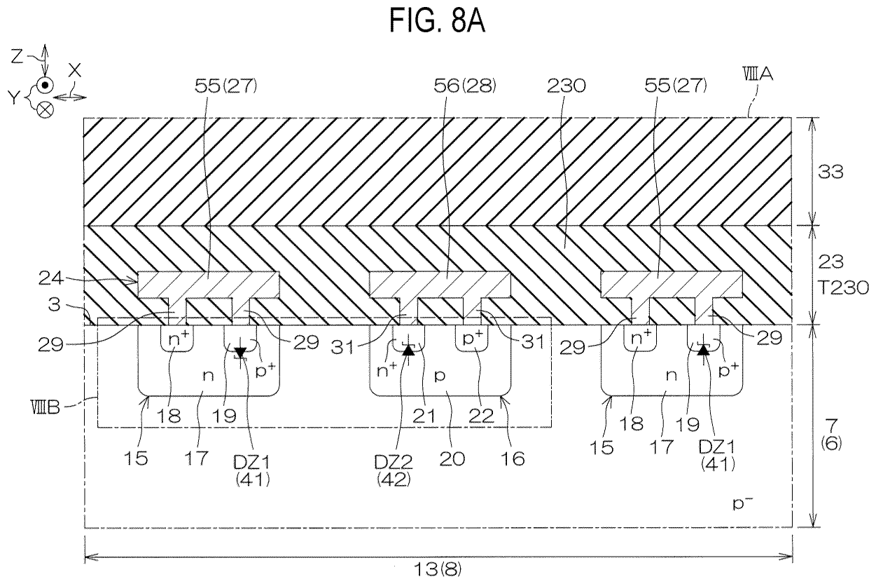

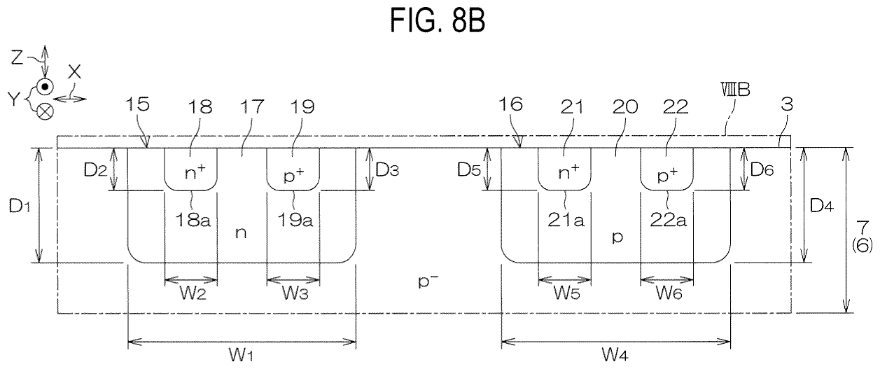

FIG. 1 is a schematic plan view of a semiconductor device 1 according to a first embodiment of the present disclosure. FIG. 2 is a cross-sectional view taken along line II-II shown in FIG. 1. FIG. 3 is a cross-sectional view taken along line III-III shown in FIG. 1. FIG. 4 is a plan view showing a layout of a first pad 9 and a second pad 11. FIG. 5 is a plan view showing a layout of a first wiring layer 24. FIG. 6 is a plan view showing a layout of a chip 2. FIG. 7 is an enlarged view of a portion surrounded by dashed line VII in FIG. 6. FIG. 8A is a cross-sectional view taken along line VIIIA-VIIIA shown in FIG. 7. FIG. 8B is an enlarged view of a portion surrounded by dashed line VIIIB in FIG. 8A.

The semiconductor device 1 includes a chip 2. The chip 2 may be called a “semiconductor chip,” a “diode chip,” or the like. The semiconductor device 1 is a small chip component (semiconductor device). In this embodiment, the semiconductor device 1 includes an electro-static discharge (ESD) protection chip configured to protect an electric circuit from ESD. The ESD protection chip protects the electric circuit by discharging an applied ESD surge to a power supply wiring or a ground wiring.

The semiconductor device 1 may be called a “diode,” a “TVS diode,” a “diode chip,” etc.

The chip 2 has a first main surface (main surface) 3 on one side, a second main surface 4 on the other side, and first to fourth side surfaces 5A to 5D connecting the first main surface 3 and the second main surface 4. The first main surface 3 and the second main surface 4 are formed in a quadrangular shape in a plan view seen from a vertical direction Z (hereinafter, simply referred to as “plan view”). The vertical direction Z is also a thickness direction of the chip 2 and a normal direction of the first main surface 3 (the second main surface 4). The first main surface 3 and the second main surface 4 may be formed in a square or rectangular shape in a plan view. In this embodiment, the first main surface 3 and the second main surface 4 are formed in a square shape (substantially a square shape) in a plan view.

Referring to FIG. 1, with respect to a circumferential direction (counterclockwise in FIG. 1) of the chip 2 starting from the first side surface 5A, the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X along the first main surface 3 and face a second direction Y that intersects (specifically, is perpendicular to) the first direction X. The second side surface 5B and the fourth side surface 5D extend in the second direction Y and face the first direction X. The first to fourth side surfaces 5A to 5D are flat surfaces extending along the vertical direction Z.

The first to fourth side surfaces 5A to 5D may have a length of 0.1 mm or more and 2 mm or less in a plan view. The length may be 0.1 mm or more and 0.2 mm or less, 0.2 mm or more and 0.3 mm or less, 0.3 mm or more and 0.4 mm or less, 0.4 mm or more and 0.5 mm or less, 0.5 mm or more and 0.6 mm or less, 0.6 mm or more and 0.7 mm or less, 0.7 mm or more and 0.8 mm or less, 0.8 mm or more and 0.9 mm or less, 0.9 mm or more and 1 mm or less, 1 mm or more and 1.2 mm or less, 1.2 mm or more and 1.4 mm or less, 1.4 mm or more and 1.6 mm or less, 1.6 mm or more and 1.8 mm or less, or 1.8 mm or more and 2 mm or less.

Referring to FIG. 2, the chip 2 includes a p-type (first conductivity type) semiconductor layer 6. The p-type semiconductor layer 6 is exposed from the second main surface 4 and the first to fourth side surfaces 5A to 5D. The semiconductor layer 6 may be called a “base region,” a “semiconductor region,” or the like.

In this embodiment, the semiconductor layer 6 is made up of a p-type semiconductor substrate 7. The p-type impurity concentration of the semiconductor substrate 7 is 1.0×10¹² cm⁻³ or more and 1.0×10¹⁴ cm⁻³ or less. Specifically, the semiconductor substrate 7 is a silicon substrate. The semiconductor substrate 7 forms a surface layer portion of the first main surface 3 and a surface layer portion of the second main surface 4 of the chip 2. The p-type impurity concentration of the semiconductor substrate 7 may be 1.0×10¹³ cm⁻³ or more and 1.0×10¹⁵ cm⁻³ or less. Since the semiconductor substrate 7 has a relatively low p-type impurity concentration, it may be called a “p-type region.” A thickness of the semiconductor substrate 7 may be 10 μm or more and 800 μm or less.

Referring to FIG. 6, a device formation region 8 where a diode device is formed on the surface layer portion of the first main surface 3, two first pad regions 10 where first pads 9 are arranged on the first main surface 3, and one second pad region 12 where a second pad 11 is arranged on the first main surface 3 are set in the chip 2. The device formation region 8, the first pad regions 10, and the second pad region 12 do not overlap with each other. In this embodiment, the device formation region 8 is a thyristor region 13 where a thyristor (reverse conducting thyristor) is formed.

The thyristor region 13 is set at an inner portion of the chip 2 while being spaced apart from a periphery (the first to fourth side surfaces 5A to 5D) of the chip 2 in a plan view. The two first pad regions 10 are a region on the side of the first side surface 5A when viewed from a central portion of the chip 2, and are formed from the second side surface 5B to the fourth side surface 5D. In addition, the one second pad region 12 is a region on the side of the third side surface 5C when viewed from the central portion of the chip 2, and is formed to be spaced apart from both the second side surface 5B and the fourth side surface 5D. The thyristor region 13 is formed in a region excluding these regions.

A first area ratio of a planar area of the thyristor region 13 to a planar area of the first main surface 3 may be 25% or more and 80% or less. The first area ratio may be 25% or more and 30% or less, 30% or more and 35% or less, 35% or more and 40% or less, 40% or more and 45% or less, 45% or more and 50% or less, 50% or more and 55% or less, 55% or more and 60% or less, 60% or more and 65% or less, 65% or more and 70% or less, 70% or more and 75% or less, or 75% or more and 80% or less. The first area ratio is preferably 40% or more and 70% or less.

The semiconductor device 1 includes a plurality of thyristor structures 14 in the thyristor region 13. The plurality of thyristor structures 14 are arranged to be inwardly spaced apart from a periphery of the thyristor region 13. In this embodiment, the plurality of thyristor structures 14 are arranged to be spaced apart from each other in the first direction X and are formed in a band shape extending in the second direction Y. That is, in this embodiment, the plurality of thyristor structures 14 are arranged in a stripe shape extending in the second direction Y. It goes without saying that the number of thyristor structures 14 is not limited to the number shown in FIG. 6, and may be more than the number shown in FIG. 6 (for example, a larger number).

Referring to FIG. 7, the plurality of thyristor structures 14 includes a plurality of first thyristor structures 15 and a plurality of second thyristor structures 16. The first thyristor structures 15 extend in a line shape in the second direction Y. The second thyristor structures 16 extend in a line shape in the second direction Y. The first thyristor structures 15 and the second thyristor structures 16 are arranged alternately in the first direction X. The first thyristor structures 15 are arranged in a stripe shape. The second thyristor structures 16 are arranged in a stripe shape.

Referring to FIGS. 7 and 8A, the first thyristor structure 15 includes a first diffusion region 17 formed on the first main surface 3. The n-type impurity concentration of the first diffusion region 17 is 1.0×10¹⁶ cm⁻³ or more and 1.0×10¹⁸ cm⁻³ or less. The n-type impurity concentration of the first diffusion region 17 is higher than the p-type impurity concentration of the semiconductor substrate 7. The first diffusion region 17 may be called an “n-type well region.” The first diffusion region 17 extends in a line shape in the second direction Y.

Referring to FIG. 8B, the first diffusion region 17 has a first width W₁ in the first direction X. The first width W₁ is, for example, 5 μm or more and 20 μm or less. A first depth D₁ of a bottom portion 17a of the first diffusion region 17 is, for example, 1 μm or more and 5 μm or less.

Referring to FIGS. 7 and 8A, the first thyristor structure 15 includes an n-type base region 18 and a p-type emitter region 19 formed in a surface layer portion of the first diffusion region 17. The n-type base region 18 and the p-type emitter region 19 extend in a line shape in the second direction Y. The p-type emitter region 19 and the n-type base region 18 are formed to be spaced apart from each other in the first direction X. The n-type base region 18 is disposed on the side of the second side surface 5B with respect to the p-type emitter region 19. The n-type base region 18 is formed to be spaced apart from a periphery of the first diffusion region 17 on the side of the second side surface 5B. The p-type emitter region 19 is formed to be spaced apart from the periphery of the first diffusion region 17 on the side of the fourth side surface 5D.

The n-type impurity concentration of the n-type base region 18 is 1.0×10¹⁹ cm⁻³ or more and 1.0×10²⁰ cm⁻³ or less. The n-type impurity concentration of the n-type base region 18 is higher than the n-type impurity concentration of the first diffusion region 17. The n-type base region 18 may be called an “n-type high concentration region,” a “first base region,” a “base region,” or the like.

Referring to FIG. 8B, the n-type base region 18 has a second width W₂ in the first direction X. The second width W₂ of the n-type base region 18 is, for example, 0.5 μm or more and 3 μm or less. The second width W₂ is narrower than the first width W₁ (W₂<W₁).

A second depth D₂ of a bottom portion 18a of the n-type base region 18 is, for example, 0.5 μm or more and 2 μm or less. The second depth D₂ is less than the first depth D₁ (D₂<D₁).

Referring to FIGS. 7 and 8A, the n-type impurity concentration of the p-type emitter region 19 is 1.0×10¹⁹ cm⁻³ or more and 1.0×10²¹ cm⁻³ or less. The p-type impurity concentration of the p-type emitter region 19 is higher than the n-type impurity concentration of the semiconductor substrate 7. The p-type impurity concentration of the p-type emitter region 19 is higher than the p-type impurity concentration of a second diffusion region 20 to be described later. The p-type emitter region 19 may be called a “p-type high concentration region,” a “first emitter region,” an “emitter region,” or the like.

Referring to FIG. 8B, the p-type emitter region 19 has a third width W₃ in the first direction X. The third width W₃ is, for example, 0.5 μm or more and 3 μm or less. The third width W₃ is narrower than the first width W₁ (W₃<W₁). In this embodiment, the third width W₃ is equal to the second width W₂ (W₃=W₂).

A third depth D₃ of a bottom portion 19a of the p-type emitter region 19 is, for example, 0.5 μm or more and 2 μm or less. The third depth D₃ is less than the first depth D₁ (D₃<D₁). In this embodiment, the third depth D₃ is equal to the second depth D₂ (D₃=D₂).

Referring to FIGS. 7 and 8A, the second thyristor structure 16 includes a second diffusion region 20 formed on the first main surface 3. The p-type impurity concentration of the second diffusion region 20 is 1.0×10¹⁶ cm⁻³ or more and 1.0×10¹⁸ cm⁻³ or less. The p-type impurity concentration of the second diffusion region 20 is higher than the p-type impurity concentration of the semiconductor substrate 7. The second diffusion region 20 may be called a “p-type well region.” The second diffusion region 20 extends in a line shape in the second direction Y.

Referring to FIG. 8B, the second diffusion region 20 has a fourth width W₄ in the first direction X. The fourth width W₄ is, for example, 5 μm or more and 20 μm or less. In this embodiment, the fourth width W₄ is equal to the first width W₁ (W₄=W₁). A fourth depth D₄ of a bottom portion 20a of the second diffusion region 20 is, for example, 1 μm or more and 5 μm or less. The fourth depth D₄ is equal to the first depth D₁ (D₄=D₁).

Referring to FIGS. 7 and 8A, the second thyristor structure 16 includes an n-type emitter region 21 and a p-type base region 22 formed in a surface layer portion of the second diffusion region 20. The n-type emitter region 21 and the p-type base region 22 extend in a line shape in the second direction Y. The p-type base region 22 is formed to be spaced apart from the n-type emitter region 21 in the first direction X. The n-type emitter region 21 is disposed on the side of the second side surface 5B with respect to the p-type base region 22. The n-type emitter region 21 is formed to be spaced apart from a periphery of the second diffusion region 20 on the side of the second side surface 5B. The p-type base region 22 is formed to be spaced apart from a periphery of the second diffusion region 20 on the side of the fourth side surface 5D.

The n-type impurity concentration of the n-type emitter region 21 is 1.0×10¹⁹ cm⁻³ or more and 1.0×10²¹ cm⁻³ or less. The n-type impurity concentration of the n-type emitter region 21 is higher than the n-type impurity concentration of the second diffusion region 20. The n-type emitter region 21 may be called an “n-type high concentration region,” a “high concentration region,” an “emitter region,” or the like.

Referring to FIG. 8B, the n-type emitter region 21 has a fifth width W₅ in the first direction X. The fifth width W₅ of the n-type emitter region 21 is, for example, 0.5 μm or more and 3 μm or less. The fifth width W₅ is narrower than the fourth width W₄ (W₅<W₄). In this embodiment, the fifth width W₅ is equal to the second width W₂ (W₅=W₂).

A fifth depth D₅ of a bottom portion 21a of the n-type emitter region 21 is, for example, 0.5 μm or more and 2 μm or less. The fifth depth D₅ is less than the fourth depth D₄ (D₅<D₄). In this embodiment, the fifth depth D₅ is equal to the second depth D₂ (D₅=D₂).

Referring to FIGS. 7 and 8A, the n-type impurity concentration of the p-type base region 22 is 1.0×10¹⁹ cm⁻³ or more and 1.0×10²¹ cm⁻³ or less. The p-type impurity concentration of the p-type base region 22 is higher than the n-type impurity concentration of the semiconductor substrate 7. The p-type impurity concentration of the p-type base region 22 is higher than the p-type impurity concentration of the second diffusion region 20. The p-type base region 22 may be called a “p-type high concentration region,” a “second base region,” a “base region,” or the like.

The p-type base region 22 has a sixth width W₆ in the first direction X. The sixth width W₆ is, for example, 0.5 μm or more and 3 μm or less. The sixth width W₆ is narrower than the fourth width W₄ (W₆<W₄). In this embodiment, the sixth width W₆ is equal to the third width W₃ (W₆=W₃). The sixth width W₆ is equal to the fifth width W₅(W₆=W₅).

Referring to FIG. 8B, a sixth depth D₆ of a bottom portion 22a of the p-type base region 22 is, for example, 0.5 μm or more and 2 μm or less. The sixth depth D₆ is less than the fourth depth D₄ (D₆<D₄). In this embodiment, the sixth depth D₆ is equal to the third depth D₃ (D₆=D₃). The sixth depth D₆ is equal to the fifth depth D₅(D₆=D₅).

Referring to FIGS. 2 and 8A, the semiconductor device 1 (the chip 2) includes an insulating layer 23 covering the first main surface 3. The insulating layer 23 collectively covers the device formation region 8 (the thyristor region 13), the two first pad regions 10, and the one second pad region 12. The insulating layer 23 covers the thyristor structure 14 (the first thyristor structure 15 and the second thyristor structure 16) in the thyristor region 13. The insulating layer 23 may be called an “interlayer insulating film,” an “insulating film,” an “interlayer film,” an “intermediate insulating film,” or the like.

In this embodiment, the insulating layer 23 is made up of a laminated wiring structure having a laminated structure in which a plurality of insulating layers and a plurality of wiring layers are alternately laminated. Each insulating layer 23 may include at least one of a silicon oxide film, a silicon nitride film, or a silicon oxynitride film. In this embodiment, each insulating layer 23 includes a silicon oxide film.

A thickness of the insulating layer 23 (thickness T230 of an upper portion 230 to be described later (FIG. 8A)) may be 3 μm or more and 30 μm or less. The thickness of the insulating layer 23 may be 1 μm or more and 2 μm or less, 2 μm or more and 4 μm or less, 4 m or more and 6 μm or less, 6 μm or more and 8 μm or less, 8 μm or more and 10 μm or less, 10 μm or more and 15 μm or less, 15 μm or more and 20 μm or less, 20 μm or more and 25 μm or less, or 25 μm or more and 30 μm or less. The thickness of the insulating layer 23 is preferably m or more and 15 μm or less.

The insulating layer 23 includes a first wiring layer 24 (FIG. 8A) disposed anywhere over the first main surface 3 via the insulating layer, and a second wiring layer 25 (FIG. 2) disposed anywhere over the first wiring layer 24 via the insulating layer. A plurality of wirings included in the first wiring layer 24 all have the same height from the first main surface 3. A plurality of wirings included in the second wiring layer 25 all have the same height from the first main surface 3. The first wiring layer 24 and the second wiring layer 25 have different heights from the first main surface 3.

Referring to FIGS. 1 and 4, the semiconductor device 1 includes two first pads (pads) 9 arranged on the insulating layer 23. The first pads 9 are metal pads. In this embodiment, the first pads 9 are formed from a metal material containing Al (aluminum).

In this embodiment, each first pad 9 is formed in a circular shape in a plan view. The first pad 9 has a peripheral portion. The first pad 9 may be called a “first metal,” a “first pad,” a “first electrode,” or the like. The first pad 9 is included in the second wiring layer 25.

Referring to FIG. 4, the two first pads 9 are arranged in a region on the side of the first side surface 5A with respect to the thyristor region 13 (see FIG. 6) in a plan view. The two first pads 9 are formed to be spaced apart from each other in the first direction X. That is, the first pads 9 include a first pad 9 on the side of the second side surface 5B and a first pad 9 on the side of the fourth side surface 5D. The first pad 9 on the side of the second side surface 5B is disposed with a narrow space from the second side surface 5B. The first pad 9 on the side of the fourth side surface 5D is disposed with a narrow space from the fourth side surface 5D.

When a center line that crosses a center position in the first direction X of the chip 2 in the second direction Y is set, the two first pads 9 are preferably formed in a layout in which the two first pads 9 are in line symmetrical to each other with respect to the center line. The two first pads 9 preferably have the same size.

Referring to FIGS. 1 and 4, the semiconductor device 1 includes one second pad (pad) 11 disposed on the insulating layer 23. The second pad 11 is a metal pad. In this embodiment, the second pad 11 is formed from a metal material including Al (aluminum). The second pad 11 functions as a cathode electrode. In this embodiment, the second pad 11 is formed in a circular shape in a plan view. The second pad 11 may be called a “second metal,” a “second pad,” a “second electrode,” or the like. The second pad 11 is included in the second wiring layer 25.

Referring to FIG. 4, the one second pad 11 is disposed in a region on the side of the third side surface 5C with respect to the thyristor region 13 (FIG. 6) in a plan view. The second pad 11 is disposed on the side of the third side surface 5C with a narrow space therebetween. The second pad 11 is preferably formed in a layout in which a center of the second pad 11 is located on a center line that crosses the central portion of the chip 2 in the second direction Y. In this embodiment, the second pad 11 has a polygonal shape that is wide in both the first direction X and the second direction Y in a plan view.

Referring to FIG. 5, the semiconductor device 1 includes a first connection structure 27 configured to electrically connect the first pad 9 and the plurality of first thyristor structures 15 (FIG. 7), and a second connection structure 28 configured to electrically connect the second pad 11 and the plurality of second thyristor structures 16 (FIG. 7) in the insulating layer 23. In this embodiment, the first connection structure 27 includes a plurality of first connection wirings 55 arranged in a stripe shape extending in the second direction Y. The first connection wirings 55 are included in the first wiring layer 24 (FIG. 8A).

Referring to FIGS. 5 and 8A, the first connection wirings 55 extend in a line shape in the second direction Y. The first connection wirings 55 are arranged over the first thyristor structures 15. The first connection wirings 55 overlap the first thyristor structures 15 in a plan view. Each first connection wiring 55 is electrically connected to the n-type base region 18 and the p-type emitter region 19 of the first thyristor structure 15 through a first lower via 29 (FIG. 8A).

An end portion of the first connection wiring 55 (an end portion on the side of the first side surface 5A) reaches a region facing a lower side of the first pad 9, and is connected to the first pad 9 through a first upper via 30 (FIG. 5) in that region. In other words, the first connection wiring 55 electrically connects the n-type base region 18 (FIG. 8A) and the p-type emitter region 19 (FIG. 8A) of the first thyristor structure 15 to the first pad 9.

Only a portion (a portion where the first upper via 30 (FIG. 5) is formed) of the first connection wiring 55 faces the first pad 9. That is, in a plan view, most of the first pad 9 does not overlap the first connection wiring 55. Therefore, the presence of the first connection wiring 55 has almost no effect on a parasitic capacitance between the first pad 9 and the insulating layer 23.

Referring to FIG. 5, in this embodiment, the second connection structure 28 includes a plurality of second connection wirings 56 arranged in a stripe shape extending in the second direction Y, and a pad wiring 57 having a shape (a polygonal shape wide in both the first direction X and the second direction Y) that matches the second pad 11 (FIG. 4) in a plan view. The plurality of second connection wirings 56 are drawn out from the pad wiring 57 in the second direction Y. The plurality of second connection wirings 56 and the pad wiring 57 are included in the first wiring layer 24 (FIG. 8A).

In this embodiment, since the second pad 11 is at the same potential as the second diffusion region 20, no parasitic capacitance is formed between the second pad 11 and the semiconductor substrate 7. Therefore, the second pad region 12 is not a region that forms a parasitic capacitance with the second pad 11. Therefore, no particular problem occurs even in a case where the pad wiring 57 is disposed so as to face the second pad 11 in a plan view.

Referring to FIGS. 5 and 8A, the second connection wiring 56 extends in a line shape in the second direction Y. The second connection wiring 56 is disposed over the second thyristor structure 16. The second connection wiring 56 overlaps the second thyristor structure 16 in a plan view.

The second connection wiring 56 is electrically connected to the n-type emitter region 21 and the p-type base region 22 of the second thyristor structure 16 through a second lower via 31 (FIG. 8A). The pad wiring 57 is electrically connected to the second pad 11 through a second upper via (not shown). As a result, the second connection structure 28 electrically connects the n-type emitter region 21 and the p-type base region 22 of the second thyristor structure 16 to the second pad 11.

The p-type emitter region 19 and the n-type first diffusion region 17 form a first pn junction 41 in the surface layer portion of the thyristor region 13. The first pn junction 41 forms a first Zener diode DZ1 in the thyristor region 13.

The p-type second diffusion region 20 and the n-type emitter region 21 form a second pn junction 42 in the surface layer portion of the thyristor region 13. The second pn junction 42 forms a second Zener diode DZ2 in the thyristor region 13.

Referring to FIGS. 1 and 2, the semiconductor device 1 includes an upper insulating film 33 that selectively covers the first pad 9 and the second pad 11 on the first main surface 3. The upper insulating film 33 includes a first pad opening 35 that exposes an inner portion of the first pad 9. The first pad opening 35 is formed in a circular shape in a plan view. The upper insulating film 33 covers a peripheral portion of the first pad 9. A first electrode surface 38 is formed by exposing the inner portion of the first pad 9 through the first pad opening 35. A connector (e.g., a bonding wire) BW is connected to the first electrode surface 38.

The upper insulating film 33 includes a second pad opening 36 that exposes an inner portion of the second pad 11. The second pad opening 36 is formed in a circular shape in a plan view. The upper insulating film 33 covers a peripheral portion of the second pad 11. A second electrode surface 39 is formed by exposing the inner portion of the second pad 11 through the second pad opening 36. A connector BW is connected to the second electrode surface 39.

The upper insulating film 33 has an outer periphery at a position spaced apart from the first to fourth side surfaces 5A to 5D. The insulating layer 23 is exposed between an outer periphery of the upper insulating film 33 and the first to fourth side surfaces 5A to 5D. An exposed portion of the insulating layer 23 is annular (specifically, rectangular annular).

The upper insulating film 33 preferably has a thickness greater than a thickness of the first pad 9 and a thickness of the second pad 11. A thickness of the upper insulating film 33 is preferably less than a thickness of the chip 2.

The upper insulating film 33 may have a laminated structure including an inorganic insulating film and an organic insulating film laminated in this order from the side of the chip 2. The upper insulating film 33 only needs to include at least one of the inorganic insulating film or the organic insulating film, and does not necessarily include the inorganic insulating film and the organic insulating film at the same time. The inorganic insulating film may include at least one of a silicon oxide film, a silicon nitride film, or a silicon oxynitride film. The inorganic insulating film preferably includes an insulating material different from that of the insulating layer 23. The organic insulating film is preferably made up of a polyimide film, a polyamide film, or a polybenzoxazole film. In this embodiment, the organic insulating film includes a polybenzoxazole film.

Referring to FIG. 5, a shield ring 37 is formed on a periphery of the semiconductor device 1 in the insulating layer 23. The shield ring 37 is formed in a rectangular annular shape along the first to fourth side faces 5A to 5D. In a plan view, the thyristor region 13, the first pad region 10, and the second pad region 12 are surrounded by the shield ring 37. The shield ring 37 is, for example, a shield wiring included in the insulating layer 23. When the chip is cut out by cutting the semiconductor device, cracks or fragments may occur at the peripheral portion of the chip. In a case where cracks or fragments occur at the peripheral portion of the chip, moisture will easily enter from outside. Therefore, in this embodiment, the shield ring 37 having a rectangular annular shape in a plan view is formed at a periphery of the insulating layer 23.

A laminated parasitic capacitance formation portion (internal parasitic capacitance formation portion) 50 is formed on the first main surface 3 in the thyristor region 13.

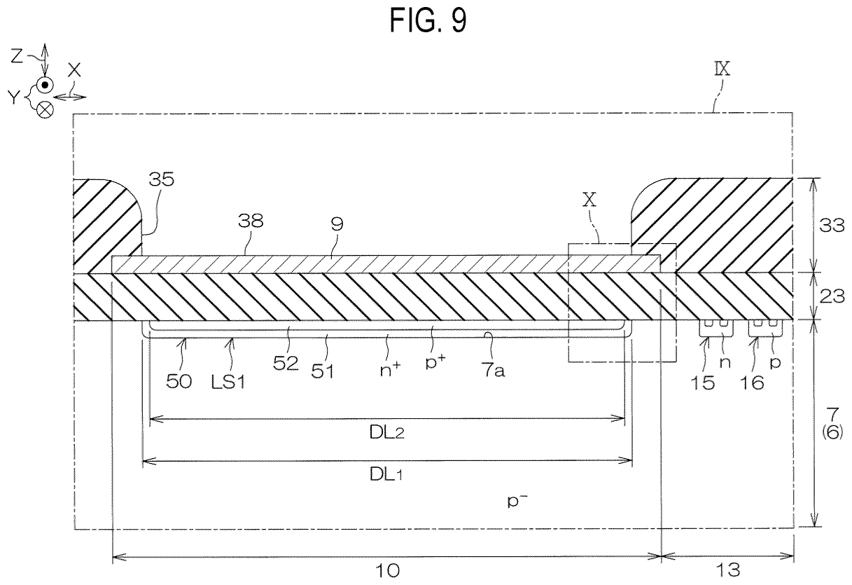

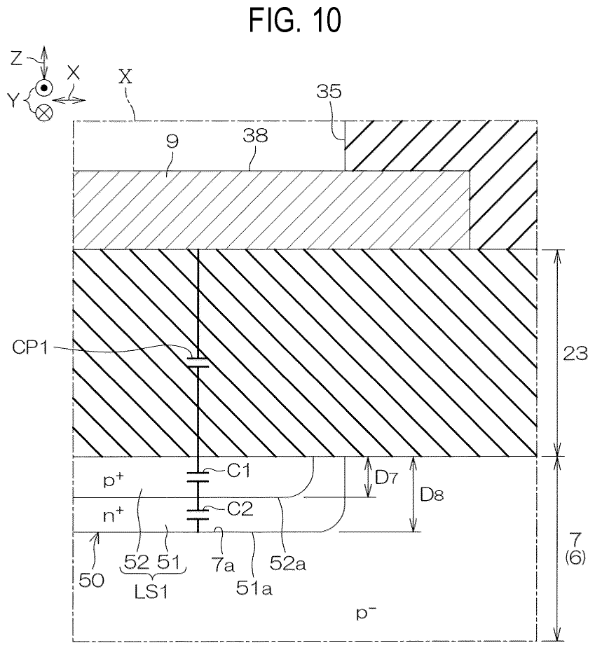

FIG. 9 is a cross-sectional view taken along line IX-IX shown in FIG. 6. FIG. 10 is an enlarged view of a portion surrounded by dashed line X in FIG. 9. The laminated parasitic capacitance formation portion 50 will be described with reference to FIGS. 6, 9, and 10.

The laminated parasitic capacitance formation portion 50 has a laminated structure LS1 of an n-type first diffusion layer 51 and a p-type second diffusion layer 52. The laminated structure LS1 (laminated parasitic capacitance formation portion 50) forms a parasitic capacitance between the semiconductor substrate 7 and the first main surface 3.

In this embodiment, the laminated structure LS1 has a circular shape in a plan view. The laminated structure LS1 overlaps the first pad 9 in a plan view. A periphery of the laminated structure LS1 is inwardly located from a periphery of the first pad 9 in a plan view. More specifically, the laminated structure LS1 overlaps the first electrode surface 38 in a plan view. A peripheral portion of the laminated structure LS1 is aligned with a periphery of the first electrode surface 38 in a plan view.

Referring to FIGS. 6 and 9, the first diffusion layer 51 is a lower layer of the laminated structure LS1. The first diffusion layer 51 is formed on the first main surface 3. In this embodiment, the first diffusion layer 51 has a circular shape in a plan view. A periphery of the first diffusion layer 51 is the periphery of the laminated structure LS1. The n-type impurity concentration of the first diffusion layer 51 is 1.0×10¹⁶ cm⁻³ or more and 1.0×10¹⁸ cm⁻³ or less. The n-type impurity concentration of the first diffusion layer 51 is higher than the p-type impurity concentration of the semiconductor substrate 7. In this embodiment, the n-type impurity concentration of the first diffusion layer 51 is the same as the n-type impurity concentration of the first diffusion region 17.

Referring to FIG. 9, a first diameter (width) DL₁ of the first diffusion layer 51 is, for example, 250 μm or more and 1 mm or less. The first diameter DL₁ is larger than the first width W₁ (FIG. 8B) of the first diffusion region 17 (DL₁>W₁). The first diameter DL₁ is larger than a fourth width W₄ (FIG. 8B) of the second diffusion region 20 (DL₁>W₄).

Referring to FIG. 10, a seventh depth D₇ of a bottom portion 51a of the first diffusion layer 51 is, for example, 1 μm or more and 5 μm or less. In this embodiment, the seventh depth D₇ is equal to the first depth D₁ (FIG. 8B) of the bottom portion 17a of the first diffusion region 17 and the fourth depth D₄ (FIG. 8B) of the bottom portion 20a of the second diffusion region 20 (D₇=D₁=D₄). The first diffusion layer 51 may be formed in the same process as the first diffusion region 17.

Referring to FIGS. 6 and 9, the second diffusion layer 52 is an upper layer of the laminated structure LS1. The second diffusion layer 52 is formed in a surface layer portion of the first diffusion layer 51. In this embodiment, the second diffusion layer 52 has a circular shape in a plan view. The second diffusion layer 52 surrounds lower and lateral sides of the first diffusion layer 51. The p-type impurity concentration of the second diffusion layer 52 is 1.0×10¹⁶ cm⁻³ or more and 1.0×10¹⁸ cm⁻³ or less. The p-type impurity concentration of the second diffusion layer 52 is higher than the p-type impurity concentration of the semiconductor substrate 7. In this embodiment, the p-type impurity concentration of the second diffusion layer 52 is the same as the p-type impurity concentration of the second diffusion region 20.

Referring to FIG. 10, a periphery of the second diffusion layer 52 is inwardly located from the periphery of the first diffusion layer 51 (periphery of the laminated structure LS1). A second diameter (width) DL₂ of the second diffusion layer 52 is, for example, 200 μm or more and 950 mm or less. The second diameter DL₂ is larger than the first width W₁ (FIG. 8B) of the first diffusion region 17 (DL₂>W₁). The second diameter DL₂ is larger than the fourth width W₄ (FIG. 8B) of the second diffusion region 20 (DL₂>W₄).

Referring to FIG. 10, an eighth depth D₈ of a bottom portion 52a of the second diffusion layer 52 is, for example, 0.7 μm or more and 3 μm or less. In this embodiment, the eighth depth D₈ is less than the seventh depth D₇ (D₈<D₇). The eighth depth D₈ is less than the first depth D₁ (FIG. 8B) of the bottom portion 17a of the first diffusion region 17 and the fourth depth D₄ (FIG. 8B) of the bottom portion 20a of the second diffusion region 20 (D₈<D₁=D₄). The eighth depth D₈ is greater than the third depth D₃ (FIG. 8B) of the bottom portion 19a of the p-type emitter region 19 and the sixth depth D₆ (FIG. 8B) of the bottom portion 22a of the p-type base region 22 (D₈>D₃=D₆).

In the laminated structure LS1, a first laminated parasitic capacitance (internal parasitic capacitance) C1 is formed between the p-type second diffusion layer 52 and the n-type first diffusion layer 51. A second laminated parasitic capacitance (internal parasitic capacitance) C2 is formed between the n-type first diffusion layer 51 and the p-type semiconductor substrate 7.

In addition, since the first pad 9 is at the same potential as the n-type first diffusion region 17, a parasitic capacitance is formed between the first pad 9 and the p-type semiconductor substrate 7. The first pad 9 faces the first pad region 10 with the insulating layer 23 sandwiched therebetween (faces a facing portion 7a on the surface of the semiconductor substrate 7 that faces the first pad 9), forming a parasitic capacitance CP1.

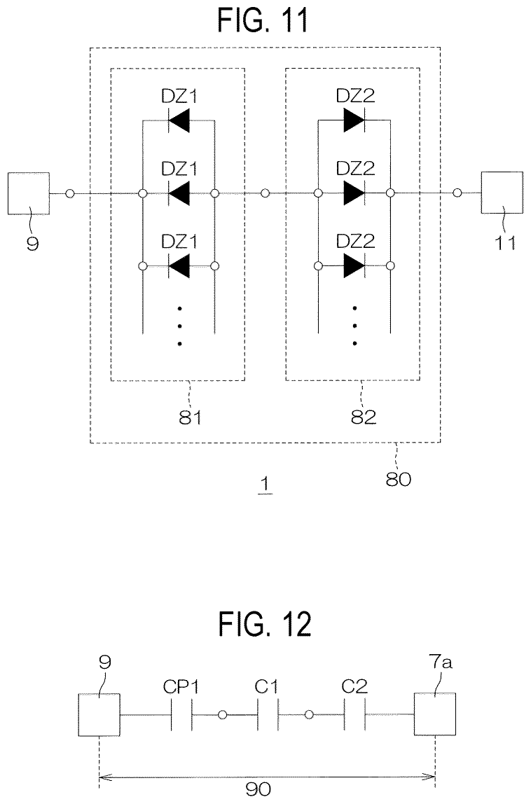

FIG. 11 is an electric circuit diagram of the semiconductor device 1. The semiconductor device 1 includes a first pad 9, a second pad 11, and a TVS circuit 80. The TVS circuit 80 is a series circuit in which a first parallel circuit 81 and a second parallel circuit 82 are connected in series, and is electrically connected to the first pad 9 and the second pad 11.

The first parallel circuit 81 includes a plurality of first Zener diodes DZ1 connected in parallel to each other. Cathodes of the plurality of first Zener diodes DZ1 are connected to the first pad 9. Anodes of the plurality of first Zener diodes DZ1 are electrically connected to the second pad 11.

The second parallel circuit 82 includes a plurality of second Zener diodes DZ2 connected in parallel to each other. Anodes of the plurality of second Zener diodes DZ2 are electrically connected to the first pad 9. Cathodes of the plurality of second Zener diodes DZ2 are electrically connected to the second pad 11.

The semiconductor device 1 is a bidirectional device configured to allow a current to flow in both directions to the first pad 9 and the second pad 11. That is, when a voltage equal to or higher than a predetermined threshold voltage with the first pad 9 being positive is applied between the first pad 9 and the second pad 11, a current flows from the first pad 9 to the second pad 11 via the first Zener diode DZ1.

On the other hand, when a voltage equal to or higher than a predetermined threshold voltage with the second pad 11 being positive is applied between the first pad 9 and the second pad 11, a current flows from the second pad 11 to the first pad 9 via the second Zener diode DZ2.

As described above, in the laminated structure LS1, the first laminated parasitic capacitance C1 is formed between the p-type second diffusion layer 52 and the n-type first diffusion layer 51. In addition, the second laminated parasitic capacitance C2 is formed between the n-type first diffusion layer 51 and the p-type semiconductor substrate 7. In addition, the first pad 9 faces the first pad region 10 with the insulating layer 23 interposed therebetween, forming the parasitic capacitance (first parasitic capacitance, second parasitic capacitance) CP1 with the insulating layer 23. In this embodiment, since a first trench 451 is not formed in the first main surface 3, a total thickness of the insulating layer 23 matches the thickness T230 of the upper portion 230. Therefore, in this embodiment, the parasitic capacitance (first parasitic capacitance) between the first pad 9 and the upper portion 230 and the parasitic capacitance (second parasitic capacitance) between the first pad 9 and the insulating layer 23 are both the parasitic capacitance CP1.

FIG. 12 is an electric circuit diagram showing the parasitic capacitance around the first pad 9 (in a portion between the first pad 9 and the facing portion 7a in the semiconductor substrate 7 that faces the first pad 9).

The semiconductor device 1 includes the first pad 9, the facing portion 7a (FIGS. 9 and 10) in the semiconductor substrate 7 that faces the first pad 9, and a first pad parasitic capacitance circuit 90. The first pad parasitic capacitance circuit 90 forms a series circuit including the first laminated parasitic capacitance C1, the second laminated parasitic capacitance C2, and the parasitic capacitance CP1. A combined capacitance CS1 around the first pad 9 is expressed by the following equation (1).

$$C S 1 = \frac{C 1 \times C 2}{C P 1 \times C 1 + C P 1 \times C 2 + C 1 \times C 2} \qquad [ Equation 1 ]$$

In contrast, consider a case where the laminated structure LS1 (the laminated parasitic capacitance formation portion 50) is removed. In this case, a combined capacitance CS1* around the first pad 9 is equal to the parasitic capacitance CP1. The combined capacitance CS1 is less than the combined capacitance CS1*. Therefore, by forming the laminated structure LS1 on the first main surface 3, the parasitic capacitance around the first pad 9 can be reduced.

As described above, according to the first embodiment, the laminated structure LS1 including the first diffusion layer 51 and the second diffusion layer 52 is formed on the first main surface 3. The first laminated parasitic capacitance C1 is formed between the p-type second diffusion layer 52 and the n-type first diffusion layer 51, and the second laminated parasitic capacitance C2 is formed between the n-type first diffusion layer 51 and the first conductivity type semiconductor substrate 7. The first pad 9 faces the first pad region 10 with the insulating layer 23 interposed therebetween, forming the parasitic capacitance CP1 with the insulating layer 23. The parasitic capacitance CP1 forms a series circuit with the first laminated parasitic capacitance C1 and the second laminated parasitic capacitance C2. This can reduce the parasitic capacitance around the first pad 9 as compared with a case where the laminated structure LS1 is not formed on the first main surface 3.

Further, the seventh depth D₇ of the bottom portion 51a of the first diffusion layer 51 is the same as the first depth D₁ of the bottom portion 17a of the first diffusion region 17. Therefore, the first diffusion layer 51 and the first diffusion region 17 can be formed in the same process. This can reduce the number of processes as compared with a case where the first diffusion layer 51 and the first diffusion region 17 are formed separately.

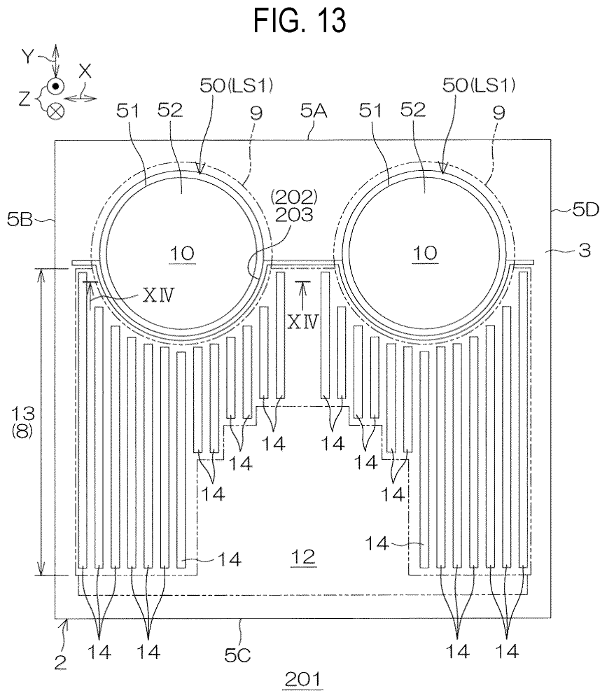

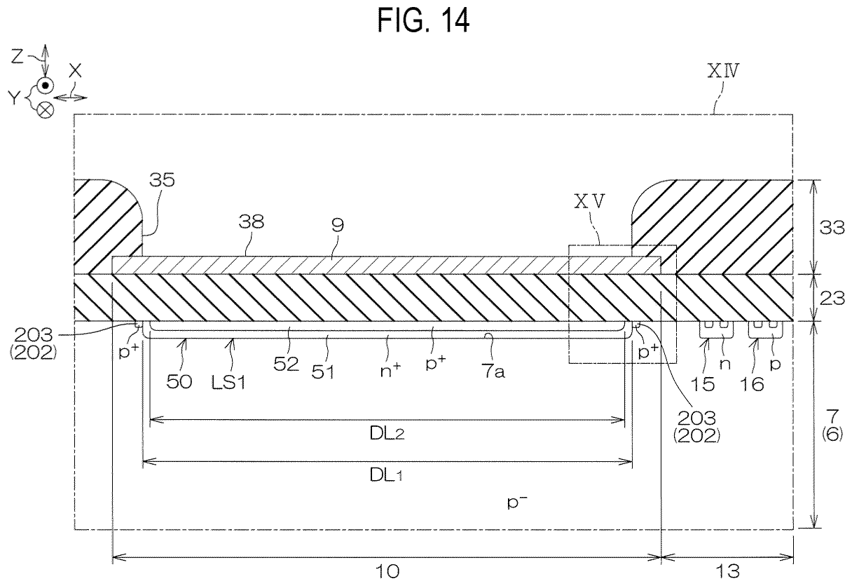

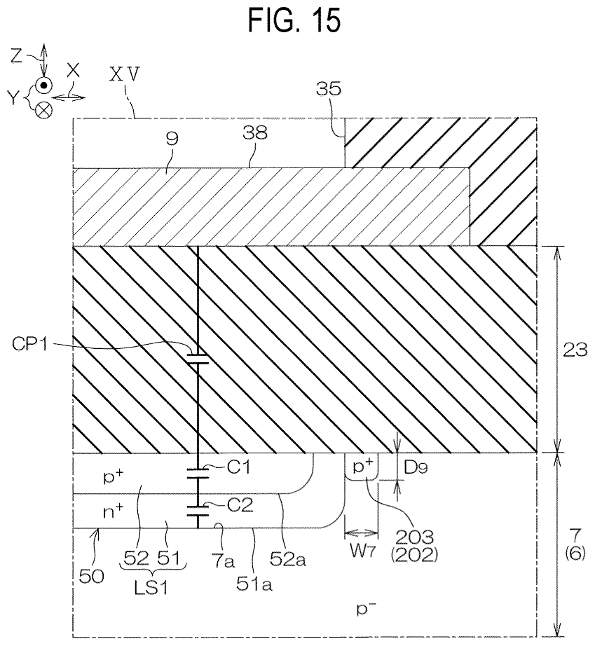

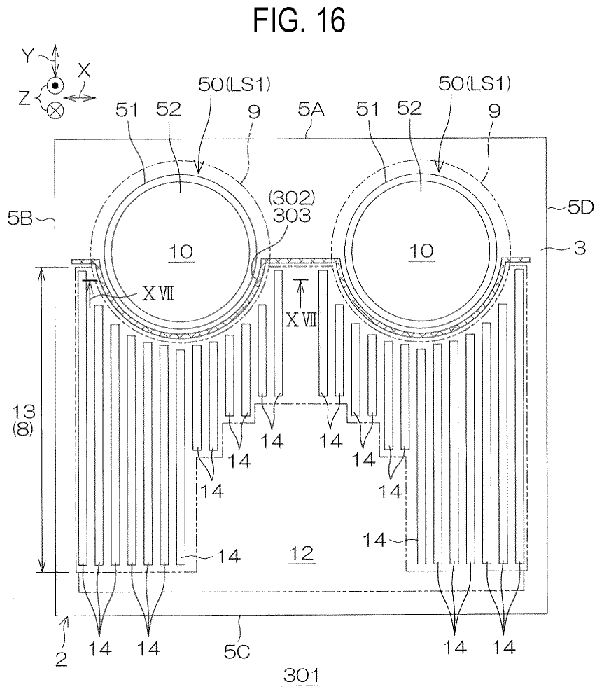

FIG. 13 is a schematic plan view of a chip 2 included in a semiconductor device 201 according to a second embodiment of the present disclosure, and corresponds to FIG. 6. FIG. 14 is a cross-sectional view taken along line XIV-XIV shown in FIG. 13. FIG. 15 is an enlarged view of a portion surrounded by dashed line XV in FIG. 14. In FIGS. 13 to 15, the same configurations as those described so far are denoted by the same reference symbols, and explanation thereof will be omitted.

The semiconductor device 201 is different from the semiconductor device 1 in that the former has an isolation portion 202, which isolates the first pad region 10 from the thyristor region 13, on the first main surface 3.

Referring to FIG. 13, the isolation portion 202 is formed in a band shape so as to cross between the n-type first diffusion layer 51 of the laminated structure LS1 and the diffusion regions 17 and 20 of the thyristor structure 14. In this embodiment, the isolation portion 202 is formed in a line shape on the first main surface 3 along a boundary between the first pad region 10 and the thyristor region 13. Isolation portions 202 corresponding to two first pad regions 10 are connected to each other.

In this embodiment, the isolation portion 202 is made up of a p-type high concentration region 203. The n-type impurity concentration of the p-type high concentration region 203 is 1.0×10¹⁹ cm⁻³ or more and 1.0×10²⁰ cm⁻³ or less. The p-type impurity concentration of the p-type high concentration region 203 is higher than the n-type impurity concentration of the semiconductor substrate 7. The p-type impurity concentration of the p-type high concentration region 203 is higher than the p-type impurity concentration of the second diffusion region 20 (FIG. 8A). The p-type impurity concentration of the p-type high concentration region 203 is equal to the p-type impurity concentrations of the p-type emitter region 19 (FIG. 8A) and the p-type base region 22 (FIG. 8A).

Referring to FIG. 15, the p-type high concentration region 203 has a seventh width W₇. The seventh width W₇ is, for example, 0.5 μm or more and 3 μm or less. The seventh width W₇ may be equal to the third width W₃ (FIG. 8B) of the p-type emitter region 19 and the sixth width W₆ (FIG. 8B) of the p-type base region 22 (W₇=W₃=W₆). The seventh width W₇ may be greater than the third width W₃ and the sixth width W₆ (W₇>W₃=W₆), or may be less than the third width W₃ and the sixth width W₆ (W₇<W₃=W₆).

A ninth depth D₉ of the p-type high concentration region 203 is, for example, 0.5 μm or more and 2 μm or less. In this embodiment, the ninth depth D₉ is equal to the third depth D₃ (FIG. 8B) of the p-type emitter region 19 and the sixth depth D₆ (FIG. 8B) of the p-type base region 22 (D₉=D₃=D₆).

Since the p-type high concentration region 203 is formed so as to cross between the n-type first diffusion layer 51 and the n-type first diffusion region 17, interference between a depletion layer spreading from the first diffusion region 17 and a depletion layer spreading from the first diffusion layer 51 can be prevented.

The semiconductor device 201 according to the second embodiment of the present disclosure achieves the same effects as those described in relation to the first embodiment.

In addition, according to the semiconductor device 201, since the p-type high concentration region 203 can prevent the interference between the depletion layer spreading from the first diffusion region 17 and the depletion layer spreading from the first diffusion layer 51, the parasitic capacitance in the first pad region 10 (the parasitic capacitance in the laminated structure LS1) can be kept even higher, and thus the parasitic capacitance around the first pad 9 can be reduced.

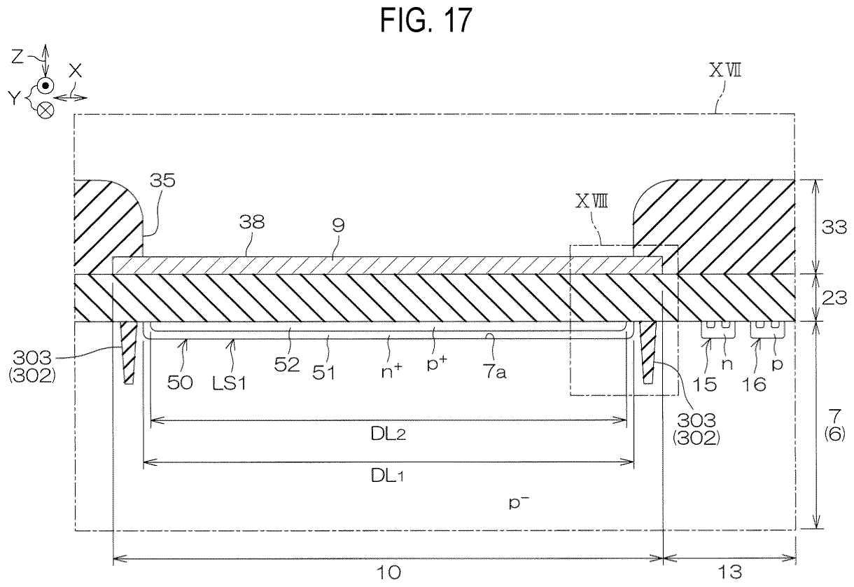

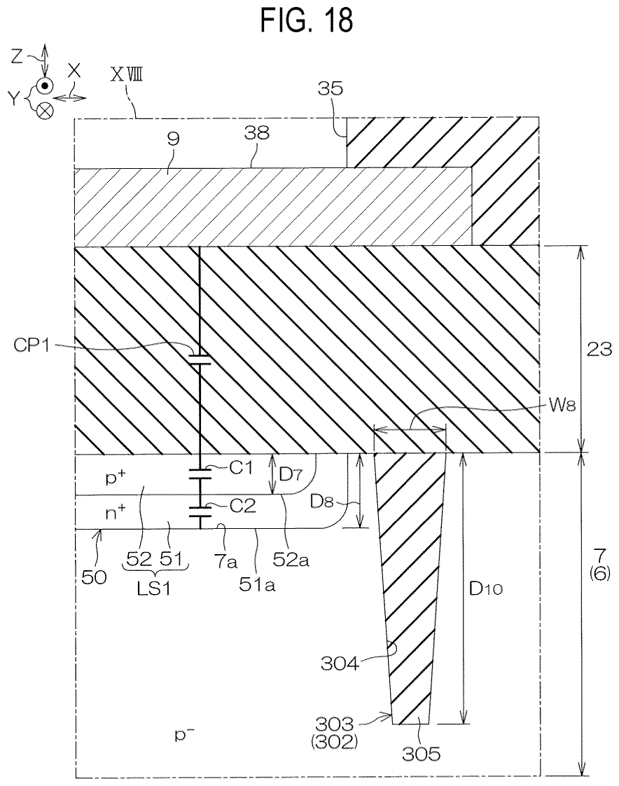

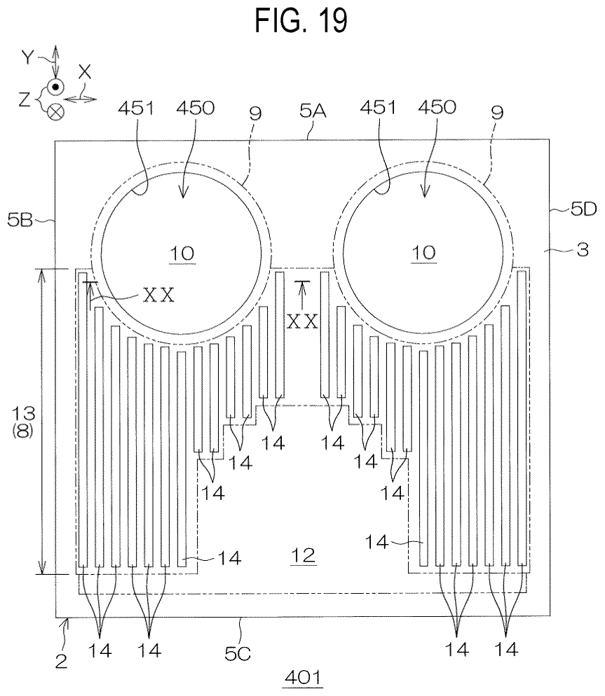

FIG. 16 is a schematic plan view of a diode chip included in a semiconductor device 301 according to a third embodiment of the present disclosure, and corresponds to FIG. 6. FIG. 17 is a cross-sectional view taken along line XVII-XVII shown in FIG. 16. FIG. 18 is an enlarged view of a portion surrounded by dashed line XVIII in FIG. 17. In FIGS. 16 to 18, the same configurations as those described so far are denoted by the same reference symbols, and explanation thereof will be omitted.

The semiconductor device 301 is different from the semiconductor device 1 in including an isolation portion 302, which isolates the first pad region 10 from the thyristor region 13, on the first main surface 3.

Referring to FIG. 16, the isolation portion 302 is formed in a band shape so as to cross between the n-type first diffusion layer 51 of the laminated structure LS1 and the diffusion regions 17 and 20 of the thyristor structure 14. In this embodiment, the isolation portion 302 is formed in a line shape on the first main surface 3 along a boundary between the first pad region 10 and the thyristor region 13. Isolation portions 302 corresponding to the two first pad regions 10 are connected to each other.

In this embodiment, the isolation portion 302 includes an insulating trench structure 303. The insulating trench structure 303 includes an insulating trench 304 and an insulator 305 formed on an inner surface of the insulating trench 304. The insulating trench structure 303 insulates the surface layer portion of the first pad region 10 from the surface layer portion of the thyristor region 13.

Referring to FIG. 18, the insulating trench 304 is formed on the first main surface 3. The insulating trench 304 has a tenth depth D₁₀. The tenth depth D₁₀ may be 1 μm or more and 50 μm or less. The tenth depth D₁₀ may be 1 μm or more and 5 μm or less, 5 μm or more and 10 μm or less, 10 μm or more and 15 μm or less, 15 μm or more and 20 μm or less, 20 μm or more and 25 μm or less, 25 μm or more and 30 μm or less, 30 μm or more and 40 μm or less, or m or more and 50 μm or less. The tenth depth D₁₀ may be greater than the depths of the diffusion regions 17 and 20 of the thyristor structure 14 (the first depth D₁ (FIG. 8B) and the fourth depth D₄ (FIG. 8B)). The insulating trench 304 may be formed in a tapered shape in which a width thereof decreases toward a bottom surface to be described later in a cross-sectional view. The tenth depth D₁₀ of the insulating trench 304 is preferably 3 μm or more and 10 μm or less.

The insulator 305 may include at least one of a silicon oxide film, a silicon nitride film, or a silicon oxynitride film. In this embodiment, the insulator 305 includes a silicon oxide film.

Since the insulating trench structure 303 insulates the surface layer portion of the first pad region 10 from the surface layer portion of the thyristor region 13, the presence of the insulating trench structure 303 prevents a flow of current between the first pad region 10 and the thyristor region 13, and thus, a current path between the first pad region 10 and the thyristor region 13 is detoured in the vertical direction Z.

The semiconductor device 301 according to the third embodiment of the present disclosure achieves the same effects as those described in relation to the first embodiment.

In addition, according to the semiconductor device 301, the insulating trench structure 303 prevents the flow of current between the first pad region 10 and the thyristor region 13, and the parasitic capacitance in the first pad region 10 (the parasitic capacitance in the laminated structure LS1) can be kept even higher, thereby reducing the parasitic capacitance around the first pad 9.

In addition, since the insulating trench structure 303 is formed deeply, a flow of current between the laminated structure LS1 and the first diffusion region 17 can be further prevented. This allows the parasitic capacitance in the first pad region 10 (the parasitic capacitance in the laminated structure LS1) to be kept even higher, thereby further reducing the parasitic capacitance around the first pad 9.

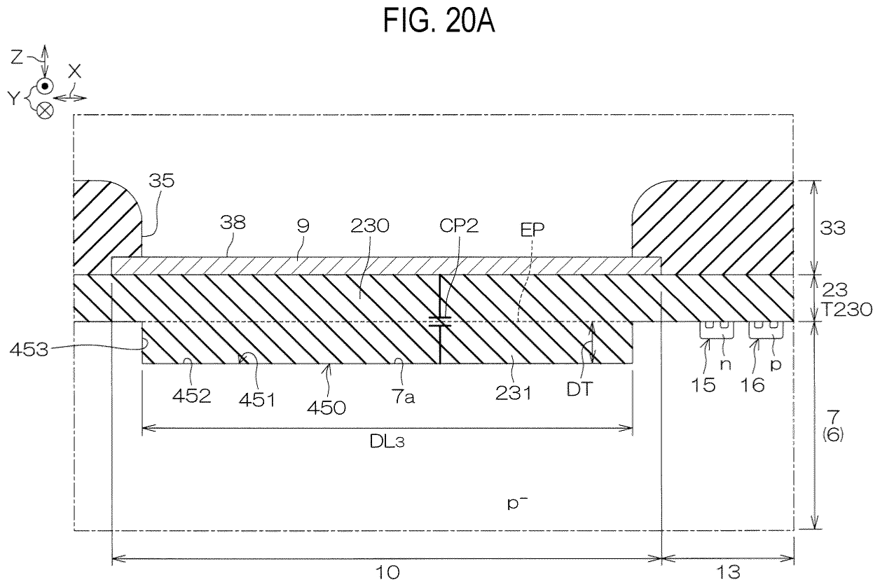

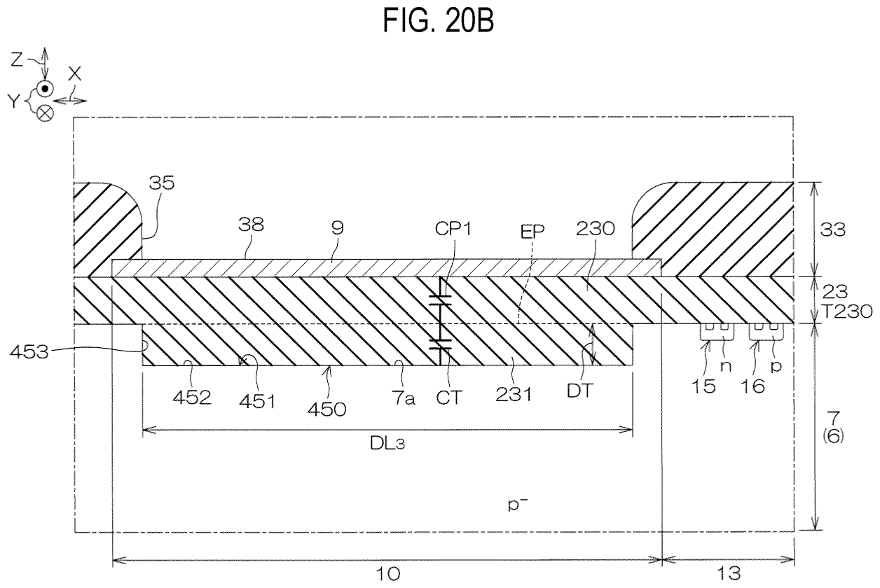

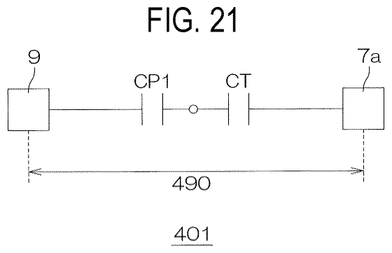

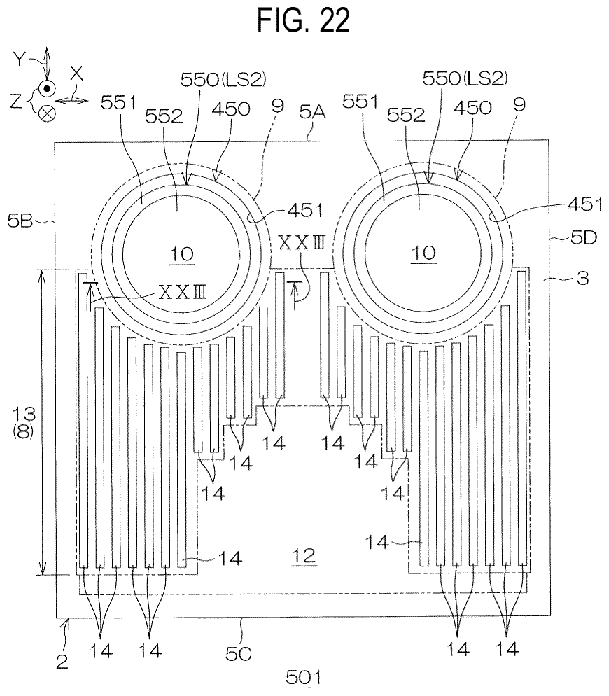

FIG. 19 is a schematic plan view of a chip 2 included in a semiconductor device 401 according to a fourth embodiment of the present disclosure, and corresponds to FIG. 6. FIGS. 20A and 20B are cross-sectional views taken along line XX-XX shown in FIG. 19. FIG. 21 is an electric circuit diagram showing parasitic capacitance around the first pad 9 (in a portion between the first pad 9 and the facing portion 7a in the semiconductor substrate 7 that faces the first pad 9) according to the fourth embodiment. In FIGS. 19 to 21, the same configurations as those described so far are denoted by the same reference symbols, and explanation thereof will be omitted.

The semiconductor device 401 includes a trench parasitic capacitance formation portion (internal parasitic capacitance formation portion) 450 formed in the first pad region 10. The trench parasitic capacitance formation portion 450 includes a first trench 451 formed in the first main surface 3 and an intra-trench insulating layer 231 buried inside the first trench 451. The intra-trench insulating layer 231 is a portion of the insulating layer 23. The semiconductor device 401 is different from the semiconductor device 1 in including the trench parasitic capacitance formation portion 450 instead of the laminated parasitic capacitance formation portion 50.

The first trench 451 of the trench parasitic capacitance formation portion 450 defines an inner surface of the trench parasitic capacitance formation portion 450 (a side surface 453 and a bottom surface 452 shown in FIGS. 20A and 20B). In this embodiment, the first trench 451 has a cylindrical shape.

The side surface 453 of the first trench 451 is a cylindrical surface. In this embodiment, the side surface 453 is perpendicular to the first main surface 3 (extends in the vertical direction Z). The side surface 453 of the first trench 451 is inwardly located from the periphery of the first pad 9 in a plan view. A peripheral portion of the first trench 451 is aligned with the periphery of the first electrode surface 38 in a plan view. The side surface 453 may be a tapered surface that narrows in diameter toward the second main surface 4.

Referring to FIGS. 20A and 20B, the side surface 453 of the first trench 451 has a third diameter (width) DL₃. The third diameter DL₃ is, for example, 250 μm or more and 1 mm or less. The third diameter DL₃ is larger than the first width W₁ (FIG. 8B) of the first diffusion region 17 (DL₃>W₁). The third diameter DL₃ is larger than the fourth width W₄ (FIG. 8B) of the second diffusion region 20 (DL₃>W₄).

The bottom surface 452 of the first trench 451 preferably has a flat extending portion (is a flat surface). It is particularly preferable that the flat portion (flat surface) of the bottom surface 452 of the first trench 451 extends substantially parallel to the first main surface 3. Of course, the bottom surface 452 of the first trench 451 may be curved in an arc shape toward the second main surface 4.

The first trench 451 has a trench depth DT in the vertical direction Z. The trench depth DT may be 3 μm or more and 30 μm or less. The trench depth DT may have a value that belongs to any one of ranges of 3 μm or more and 5 μm or less, 5 μm or more and 10 μm or less, m or more and 15 μm or less, 15 μm or more and 20 μm or less, 20 μm or more and 25 m or less, or 25 μm or more and 30 μm or less. It is more preferable that the trench depth DT is 5 μm or more and 15 μm or less.

In this embodiment, the trench depth DT is greater than the first depth D₁ (FIG. 8B) of the bottom portion 17a of the first diffusion region 17 and the fourth depth D₄ (FIG. 8B) of the bottom portion 20a of the second diffusion region 20 (DT>D₁=D₄). In this embodiment, the trench depth DT is preferably smaller than the third diameter DL₃ of the side surface 453.

The intra-trench insulating layer 231 of the trench parasitic capacitance formation portion 450 is located below an extended surface EP of the first main surface 3 (hereinafter, simply referred to as an “extended surface EP”) in the surface layer portion (a formation region of the first trench 451) of the first main surface 3. In the present disclosure, the extended surface EP is a virtual surface that is on the same plane as the first main surface 3 over the first trench 451. The intra-trench insulating layer 231 is a portion of the insulating layer 23. In other words, the insulating layer 23 includes an upper portion 230 located over the first main surface 3 and the extended surface EP, and the intra-trench insulating layer 231. In this embodiment, a thickness of the intra-trench insulating layer 231 corresponds to the trench depth DT of the first trench 451.

In this embodiment, the intra-trench insulating layer 231 has a columnar shape. The intra-trench insulating layer 231 may include at least one of a silicon oxide film, a silicon nitride film, or a silicon oxynitride film. In this embodiment, the intra-trench insulating layer 231 includes a silicon oxide film.

In this embodiment, the intra-trench insulating layer 231 overlaps the first pad 9 in a plan view. More specifically, the intra-trench insulating layer 231 overlaps the first electrode surface 38 in a plan view.

The first pad 9 faces the first pad region 10 with the insulating layer 23 (the upper portion 230 and the intra-trench insulating layer 231) interposed therebetween. The first pad 9 forms a parasitic capacitance (third parasitic capacitance) CP2 (FIG. 20A) with the facing portion 7a in the semiconductor substrate 7 that faces the first pad 9. In this embodiment, a total thickness of the insulating layer 23 is a total thickness of the thickness T230 of the upper portion 230 and the trench depth DT. Since the parasitic capacitance is inversely proportional to a distance between electrodes, a parasitic capacitance CP2 between the first pad 9 and the insulating layer 23 is lower than that in a case where the first trench 451 is not formed on the first main surface 3 (as compared with the first embodiment). Therefore, by forming the first trench 451 on the first main surface 3 and burying the intra-trench insulating layer 231 in the first trench 451, the parasitic capacitance around the first pad 9 can be reduced. In this embodiment, the parasitic capacitance CP2 is a parasitic capacitance between the first pad 9 and the facing portion 7a formed on the bottom surface 452.

As described above, according to the fourth embodiment, the trench parasitic capacitance formation portion 450 is formed on the first main surface 3 so as to face the first pad 9 with an insulating layer interposed therebetween. As compared with a case where the first trench 451 is not formed on the first main surface 3, a distance between the first pad 9 and the facing portion 7a can be kept large. Since the parasitic capacitance is inversely proportional to a distance between electrodes, by keeping the distance between the first pad 9 and the facing portion 7a large, the parasitic capacitance around the first pad 9 can be reduced as compared with a case where the trench parasitic capacitance formation portion 450 is not formed on the first main surface 3.

Referring to FIG. 20B, from another point of view, the intra-trench insulating layer 231 forms a parasitic capacitance CP1 (FIG. 20B) between the semiconductor substrate 7 and the extended surface EP. In addition, the trench parasitic capacitance formation portion 450 forms a trench parasitic capacitance CT (internal parasitic capacitance, FIG. 20B) between the semiconductor substrate 7 and the extended surface EP. In this case, the parasitic capacitance CP1 forms a series circuit with the trench parasitic capacitance CT.

Referring to FIG. 21, the semiconductor device 401 includes the first pad 9, the facing portion 7a (FIG. 20B) in the semiconductor substrate 7 that faces the first pad 9, and a first pad parasitic capacitance circuit 490. The first pad parasitic capacitance circuit 490 forms a series circuit including the trench parasitic capacitance CT and the parasitic capacitance CP1. A combined capacitance CS2 around the first pad 9 is expressed by the following equation (2).

$$C S 2 = \frac{C T}{C P 1 + C T} \times C P 1 \qquad [ Equation 2 ]$$

In contrast, a case where the trench parasitic capacitance formation portion 450 is removed is considered. In this case, a combined capacitance CS2* is equal to the parasitic capacitance CP1. The combined capacitance CS2 is less than the combined capacitance CS2*. Therefore, by forming the trench parasitic capacitance formation portion 450 on the first main surface 3, the parasitic capacitance around the first pad 9 can be reduced.

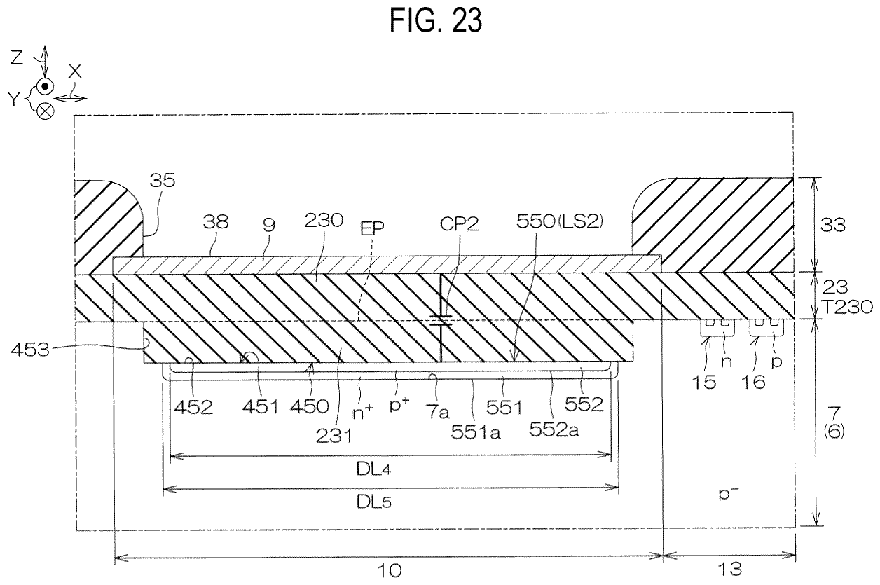

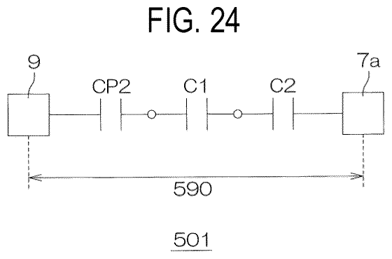

FIG. 22 is a schematic plan view of a chip 2 included in a semiconductor device 501 according to a fifth embodiment of the present disclosure, and corresponds to FIG. 6. FIG. 23 is a cross-sectional view taken along line XXIII-XXIII shown in FIG. 22. FIG. 24 is an electric circuit diagram showing parasitic capacitance around the first pad 9 according to the fifth embodiment. In FIGS. 22 to 24, the same configurations as those described so far are denoted by the same reference symbols, and explanation thereof will be omitted.

The semiconductor device 501 includes a laminated parasitic capacitance formation portion (internal parasitic capacitance formation portion) 550 in addition to the trench parasitic capacitance formation portion 450. The semiconductor device 501 is different from the semiconductor device 401 according to the fourth embodiment in including the laminated parasitic capacitance formation portion 550.

The laminated parasitic capacitance formation portion 550 has a laminated structure LS2 of an n-type first diffusion layer 551 and a p-type second diffusion layer 552. The laminated structure LS2 (the laminated parasitic capacitance formation portion 550) forms a parasitic capacitance between the semiconductor substrate 7 and the bottom surface 452 of the first trench 451.

In this embodiment, the laminated structure LS2 has a circular shape in a plan view. A periphery of the laminated structure LS2 is located to be inwardly spaced apart from the periphery of the bottom surface 452 of the first trench 451 in a plan view. In this embodiment, a peripheral portion of the laminated structure LS2 is inwardly located from the periphery of the first electrode surface 38 in a plan view.

The laminated structure LS2 is different from the laminated structure LS1 in that it is formed on the bottom surface 452 of the first trench 451 and in that the peripheral portion of the laminated structure LS2 is inwardly located from the periphery of the first electrode surface 38 in a plan view. In other respects, the laminated structure LS2 has the same configurations as the laminated structure LS1.

The first diffusion layer 551 is a lower layer of the laminated structure LS2. A periphery of the first diffusion layer 551 is the periphery of the laminated structure LS2. The n-type impurity concentration of the first diffusion layer 551 is 1.0×10¹⁶ cm⁻³ or more and 1.0×10¹⁸ cm⁻³ or less. The n-type impurity concentration of the first diffusion layer 551 is higher than the p-type impurity concentration of the semiconductor substrate 7. In this embodiment, the n-type impurity concentration of the first diffusion layer 551 is the same as the n-type impurity concentration of the first diffusion region 17.

A fourth diameter (width) DL₄ of the first diffusion layer 551 is smaller than the third diameter DL₃ of the first trench 451 (DL₄<DL₃). The fourth diameter DL₄ is larger than the first width W₁ (FIG. 8B) of the first diffusion region 17 (DL₄>W₁). The fourth diameter DL₄ is larger than the fourth width W₄ (FIG. 8B) of the second diffusion region 20 (DL₄>W₄). A depth of a bottom portion 551a of the first diffusion layer 551 is the same as the seventh depth D₇ (FIG. 8B) of the bottom portion 51a of the first diffusion layer 51.

The second diffusion layer 552 is an upper layer of the laminated structure LS2. Lower and lateral sides of the second diffusion layer 552 are surrounded by the first diffusion layer 551. A p-type impurity concentration of the second diffusion layer 552 is 1.0×10¹⁶ cm⁻³ or more and 1.0×10¹⁸ cm⁻³ or less. The p-type impurity concentration of the second diffusion layer 552 is higher than the p-type impurity concentration of the semiconductor substrate 7. In this embodiment, the p-type impurity concentration of the second diffusion layer 552 is the same as the p-type impurity concentration of the second diffusion region 20.

A periphery of the second diffusion layer 552 is inwardly located from the periphery of the first diffusion layer 551 (the periphery of the laminated structure LS2). A fifth diameter (width) DL₅ of the second diffusion layer 552 is smaller than the fourth diameter (width) DL₄ of the first diffusion layer 551 (DL₅<DL₄). The fifth diameter DL₅ of the second diffusion layer 552 is smaller than the third diameter DL₃ of the first trench 451 (DL₅<DL₃). The fifth diameter DL₅ is larger than the first width W₁ (FIG. 8B) of the first diffusion region 17 (DL₅>W₁). The fifth diameter DL₅ is larger than the fourth width W₄ (FIG. 8B) of the second diffusion region 20 (DL₅>W₄). A depth of a bottom portion 552a of the second diffusion layer 552 is the same as the eighth depth D₈ (FIG. 8B) of the bottom portion 51a of the first diffusion layer 51.

In the laminated structure LS2, a first laminated parasitic capacitance C1 is formed between the p-type second diffusion layer 552 and the n-type first diffusion layer 551. In addition, a second laminated parasitic capacitance C2 is formed between the n-type first diffusion layer 551 and the p-type semiconductor substrate 7. In addition, the first pad 9 faces the first pad region 10 with the insulating layer 23 interposed therebetween (faces the facing portion 7a on the surface of the semiconductor substrate 7 that faces the first pad 9), forming a parasitic capacitance CP2.

Referring to FIG. 24, the semiconductor device 501 includes the first pad 9, the facing portion 7a (FIG. 23) in the semiconductor substrate 7 that faces the first pad 9, and a first pad parasitic capacitance circuit 590. The first pad parasitic capacitance circuit 590 forms a series circuit including the first laminated parasitic capacitance C1, the second laminated parasitic capacitance C2, and the parasitic capacitance CP2. A combined capacitance CS3 around the first pad 9 is expressed by the following equation (3).

$$C S 3 = \frac{C 1 \times C 2}{C P 2 \times C 1 + C P 2 \times C 2 + C 1 \times C 2} \qquad [ Equation 3 ]$$

In contrast, a case where the laminated structure LS2 (the laminated parasitic capacitance formation portion 550) is removed from the bottom surface 242 of the first trench 241 (i.e., the case of the fourth embodiment) is considered. In this case, a combined capacitance CS3* corresponds to the combined capacitance CS3. The combined capacitance CS3 is less than the combined capacitance CS3*. Therefore, by forming the laminated structure LS2 on the first main surface 3, the parasitic capacitance around the first pad 9 can be further reduced.

The semiconductor device 501 according to the fifth embodiment of the present disclosure achieves the same effects as those described in relation to the fourth embodiment.

Further, according to the semiconductor device 501, in the first pad region 10, the laminated structure LS2 including the first diffusion layer 551 and the second diffusion layer 552 is formed on the bottom surface 452 of the first trench 451. The first laminated parasitic capacitance C1 is formed between the p-type second diffusion layer 552 and the n-type first diffusion layer 551, and the second laminated parasitic capacitance C2 is formed between the n-type first diffusion layer 551 and the first conductivity type semiconductor substrate 7. The first pad 9 faces the first pad region 10 with the insulating layer 23 interposed therebetween, forming the parasitic capacitance CP2. The parasitic capacitance CP2 forms a series circuit with the first laminated parasitic capacitance C1 and the second laminated parasitic capacitance C2. This can reduce the parasitic capacitance around the first pad 9 as compared with the fourth embodiment.

Further, the semiconductor device 501 according to the fifth embodiment of the present disclosure achieves the same effects as those described in relation to the first embodiment.

Further, according to the semiconductor device 501 relating to the fifth embodiment of the present disclosure, in the first pad region 10, the trench parasitic capacitance formation portion 450 is formed in the first main surface 3. As compared with a case where the first trench 451 is not formed on the first main surface 3, a distance between the first pad 9 and the facing portion 7a can be kept large. Since the parasitic capacitance is inversely proportional to a distance between electrodes, by keeping the distance between the first pad 9 and the facing portion 7a large, the parasitic capacitance around the first pad 9 can be reduced as compared with the first embodiment.

Although a plurality of embodiments of the present disclosure has been described above, the present disclosure may also be implemented in other forms.

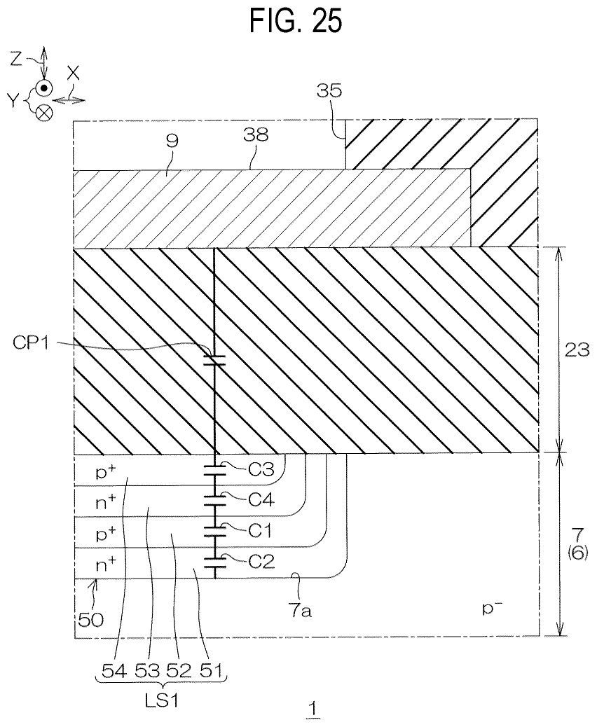

As shown in FIG. 25, in the semiconductor device 1 according to the first embodiment, the laminated structure LS1 of the laminated parasitic capacitance formation portion 50 may be a multi-layer structure including more than two layers. In the example of FIG. 25, the laminated structure LS1 is a four-layer structure. In the example of FIG. 25, the laminated structure LS1 includes a first diffusion layer 51, a second diffusion layer 52, an n-type third diffusion layer 53 formed in a surface layer portion of the second diffusion layer 52, and a p-type fourth diffusion layer 54 formed in a surface layer portion of the third diffusion layer 53.

The third diffusion layer 53 is an intermediate layer of the laminated structure LS1. In this embodiment, the third diffusion layer 53 has a circular shape in a plan view. The third diffusion layer 53 surrounds lower and lateral sides of the second diffusion layer 52. An n-type impurity concentration of the third diffusion layer 53 is 1.0×10¹⁶ cm⁻³ or more and 1.0×10¹⁸ cm⁻³ or less. The n-type impurity concentration of the third diffusion layer 53 may be the same as the n-type impurity concentration of the first diffusion layer 51. The n-type impurity concentration of the third diffusion layer 53 may be higher than the n-type impurity concentration of the first diffusion layer 51, or may be lower than the n-type impurity concentration of the first diffusion layer 51.

The fourth diffusion layer 54 is an uppermost layer of the laminated structure LS1. In this embodiment, the fourth diffusion layer 54 has a circular shape in a plan view. The fourth diffusion layer 54 surrounds the lower and lateral sides of the first diffusion layer 51. The p-type impurity concentration of the fourth diffusion layer 54 is 1.0×10¹⁶ cm⁻³ or more and 1.0×10¹⁸ cm⁻³ or less. The p-type impurity concentration of the fourth diffusion layer 54 may be higher than the n-type impurity concentration of the second diffusion layer 52, or may be lower than the n-type impurity concentration of the second diffusion layer 52.

In the example of FIG. 25, a first laminated parasitic capacitance C1 is formed between the p-type second diffusion layer 52 and the n-type first diffusion layer 51. A second laminated parasitic capacitance C2 is formed between the n-type first diffusion layer 51 and the p-type semiconductor substrate 7. A third laminated parasitic capacitance (internal parasitic capacitance) C3 is formed between the p-type fourth diffusion layer 54 and the n-type third diffusion layer 53. A fourth laminated parasitic capacitance (internal parasitic capacitance) C4 is formed between the n-type third diffusion layer 53 and the p-type second diffusion layer 52. In addition, the first pad 9 faces the first pad region 10 with the insulating layer 23 interposed therebetween, forming a parasitic capacitance CP1.

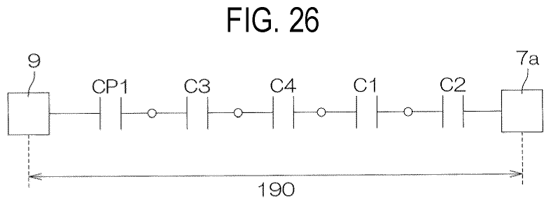

As shown in FIG. 26, the semiconductor device 1 includes the first pad 9, the facing portion 7a (FIG. 25) in the semiconductor substrate 7 that faces the first pad 9, and a first pad parasitic capacitance circuit 190. The first pad parasitic capacitance circuit 190 forms a series circuit including the third laminated parasitic capacitance C3, the fourth laminated parasitic capacitance C4, the first laminated parasitic capacitance C1, the second laminated parasitic capacitance C2, and the parasitic capacitance CP1. A combined capacitance CS4 around the first pad 9 is expressed by the following equation (4).

$$C S 4 = C 1 \times C 2 \times C 3 \times C 4 / ( C P 1 \times C 1 \times C 2 \times C 3 + C P 1 \times C 1 \times C 2 \times C 4 + C P 1 \times C 1 \times C 3 \times C 4 + C P 1 \times C 2 \times C 3 \times C 4 + C 1 \times C 2 \times C 3 \times C 4 ) \times C P 1 \qquad [ Eq . 4 ]$$

Therefore, by making the laminated structure LS1 a multi-layer structure including three or more layers, the parasitic capacitance around the first pad 9 can be further reduced.

A modification (first modification) shown in FIGS. 25 and 26 may be applied to the laminated parasitic capacitance formation portion 550 (the laminated structure LS2) of the fourth and fifth embodiments.

The laminated structures LS1 and LS2 are not limited to a four-layer laminated structure. The laminated structures LS1 and LS2 may not include the fourth diffusion layer 54, and may be a three-layer structure. The laminated structures LS1 and LS2 may further include an n-type fifth diffusion layer formed in a surface layer portion of the fourth diffusion layer 54, and may be a laminated structure including five or more layers.

The modification (first modification) shown in FIGS. 25 and 26 may be combined with any embodiments (including modifications) other than the first, fourth, and fifth embodiments.

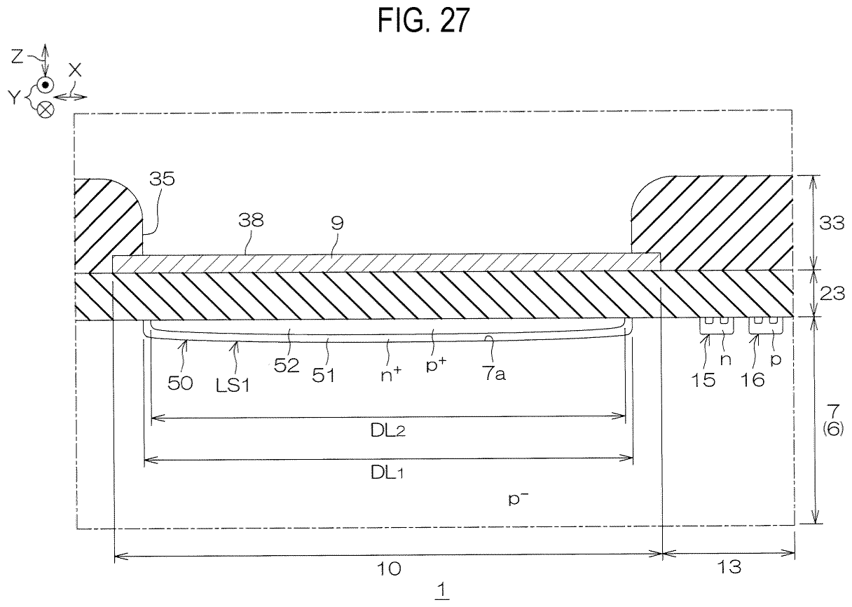

In addition, as shown in FIG. 27, in the semiconductor device 1 according to the first embodiment, the bottom portion of the first diffusion layer 51 and the bottom portion of the second diffusion layer 52 may not be flat, but may have a curved surface that is convex in a downward direction. The bottom portion of the first diffusion layer 51 and the bottom portion of the second diffusion layer 52 may have a spherical surface that is convex in the downward direction. Central portions of the bottom portion of the first diffusion layer 51 and the bottom portion of the second diffusion layer 52 may be the deepest portions.

In this case, a contact area between the first diffusion layer 51 and the second diffusion layer 52 can be increased as compared with a case where the bottom portion of the first diffusion layer 51 and the bottom portion of the second diffusion layer 52 are flat. This can increase the parasitic capacitance of the laminated structure LS1, thereby further reducing the parasitic capacitance around the first pad 9.

A modification (second modification) shown in FIG. 27 may be combined with any embodiments (including modifications) other than the first embodiment.

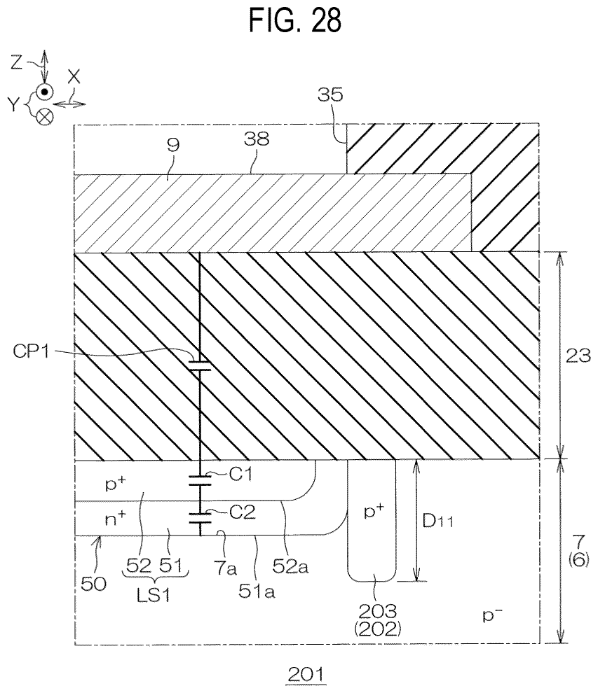

As shown in FIG. 28, a depth (eleventh depth D₁₁) of the p-type high concentration region 203 may be greater than the third depth D₃ (FIG. 8B) of the p-type emitter region 19 and the sixth depth D₆ (FIG. 8B) of the p-type base region 22 (D₁₁>D₃=D₆). The eleventh depth D₁₁ may be greater than the first depth D₁ (FIG. 8B) of the first diffusion region 17 and the fourth depth D₄ (FIG. 8B) of the second diffusion region 20 (D₁₁>D₁=D₄). The eleventh depth D₁₁ may be greater than the seventh depth D₇ (FIG. 10) of the bottom portion 51a of the first diffusion layer 51 (D₁₁>D₇). A modification (third modification) shown in FIG. 28 may be combined with any embodiments (including modifications) other than the second embodiment.

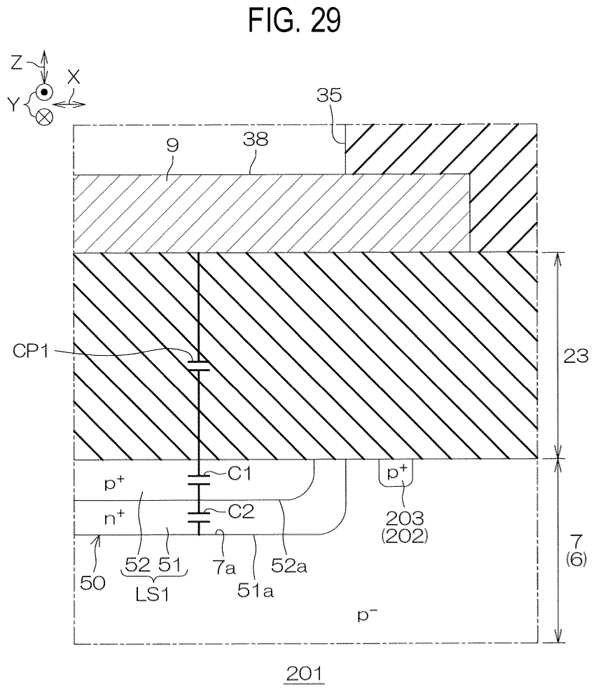

As shown in FIG. 29, the p-type high concentration region 203 may not be in contact with the first diffusion layer 51 (the laminated structure LS1), and may be formed to be spaced apart from the periphery of the first diffusion layer 51 (the laminated structure LS1). A modification (fourth modification) shown in FIG. 29 may be combined with any embodiments (including modifications) other than the second embodiment.

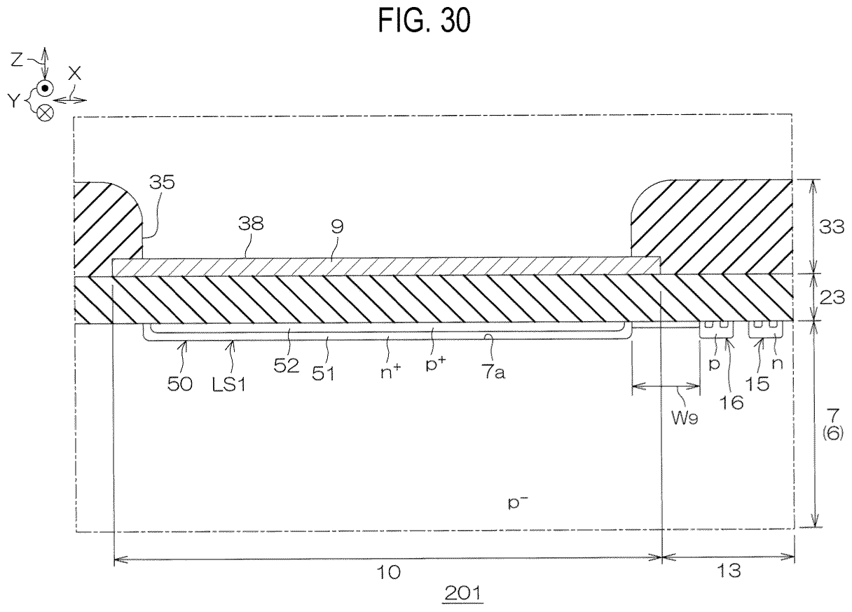

In addition, as shown in FIG. 30, in a case where the first thyristor structure 15 (i.e., the n-type first diffusion region 17 (FIG. 8A)) is adjacent to the laminated parasitic capacitance formation portion 50 (the laminated structure LS1), the p-type high concentration region 203 may be in contact with the first thyristor structure 15 (the first diffusion region 17 (FIG. 8A)). In the example of FIG. 30, the p-type high concentration region 203 is in contact with both the first diffusion layer 51 (the laminated structure LS1) and the first thyristor structure 15 (the first diffusion region 17 (FIG. 8A)). A modification (fifth modification) shown in FIG. 30 may be combined with any embodiments (including modifications) other than the second embodiment.

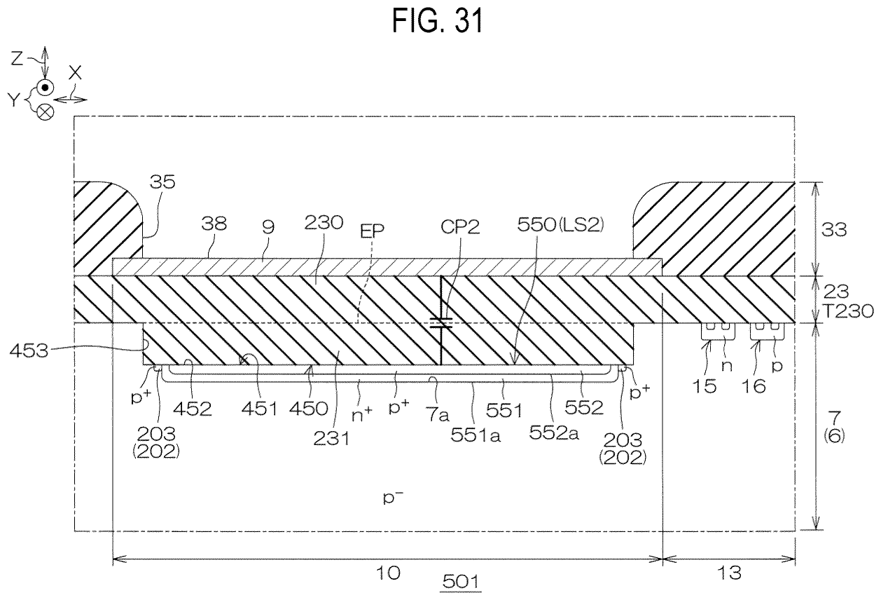

As shown in FIG. 31, the p-type high concentration region 203 (the isolation portion 202) according to the second embodiment may be applied to the semiconductor device 501 according to the fifth embodiment. In this case, the p-type high concentration region 203 is formed on the bottom surface 452 of the first trench 451. A modification (sixth modification) shown in FIG. 31 may be combined with any embodiments (including modifications) other than the second embodiment.

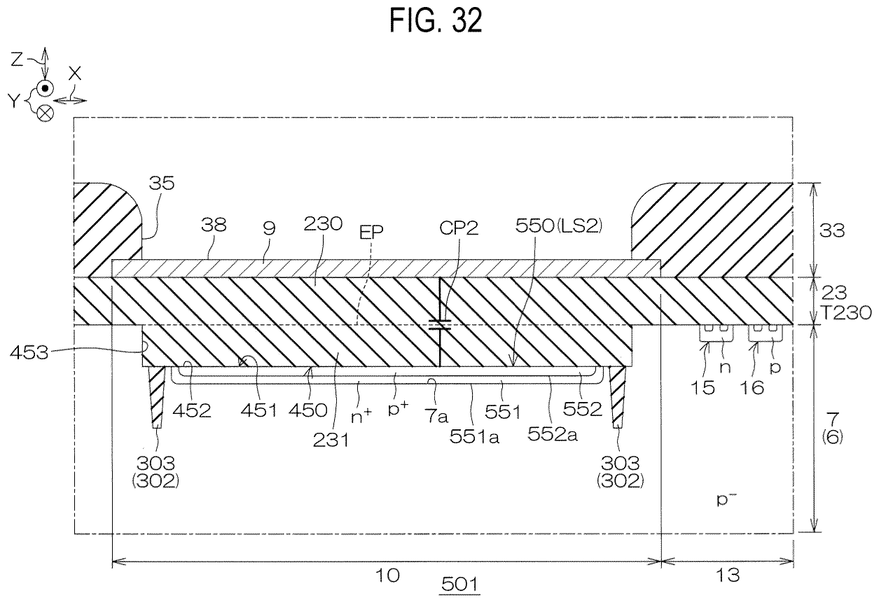

As shown in FIG. 32, the insulating trench structure 303 (the isolation portion 302) according to the third embodiment may be applied to the semiconductor device 501 according to the fifth embodiment. In this case, the insulating trench structure 303 is formed on the bottom surface 452 of the first trench 451. A modification (seventh modification) shown in FIG. 32 may be combined with any embodiments (including modifications) other than the second embodiment.

In addition, the semiconductor layer 6 does not have to be constituted only by the semiconductor substrate 7, but may have, for example, a laminated structure of the semiconductor substrate 7 and a semiconductor layer (for example, an epitaxial layer). In this case, the first thyristor structure 15, the second thyristor structure 16, the laminated parasitic capacitance formation portions 50 and 550, the trench parasitic capacitance formation portion 450, etc. may be formed in the semiconductor layer (for example, an epitaxial layer).

In the above-described embodiments, the examples in which the first conductivity type is p-type and the second conductivity type is n-type have been described, but the first conductivity type may be n-type and the second conductivity type may be p-type. A specific configuration in such a case can be obtained by replacing the p-type region with an n-type region and replacing the n-type region with a p-type region in the above description and the accompanying drawings.

The above-described embodiments of the present disclosure are illustrative in all respects and should not be construed as being limited, and it is intended that modifications are included in all respects.

The following features may be extracted from the description of the present disclosure and the drawings. Hereinafter, alphanumeric characters in parentheses represent corresponding constituent elements in the above-described embodiments, but are not intended to limit the scope of each clause to the embodiments.

### [Supplementary Note A-1]

A semiconductor device (1, 201, 301, 401, 501) including:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) so as to cover the first diffusion region (17) and the second diffusion region (20);
a first pad (9) disposed on the insulating layer (23) and electrically connected to the first diffusion region (17); and
an internal parasitic capacitance formation portion (50, 450, 550) formed in a surface layer portion of the semiconductor layer (6) and forming an internal parasitic capacitance (C1, C2, C3, C4, CT) between a facing portion (7a) in the semiconductor layer (6) that faces the first pad (9) with the insulating layer (23) interposed therebetween and the main surface (3) or an extended surface (EP) flush with the main surface (3),
wherein the first pad (9) forms a first parasitic capacitance (CP1) connected in series to the internal parasitic capacitance (C1, C2, C3, C4, CT) between the first pad (9) and an upper portion (230) of the insulating layer (23) that is formed over the main surface (3) or the extended surface (EP).

The first pad (9) is at the same potential as the first diffusion region (17) of the second conductivity type. Therefore, a parasitic capacitance is formed between the first pad (9) and the semiconductor layer (6) of the first conductivity type.

According to this configuration, the internal parasitic capacitance formation portion (50, 450, 550) is formed in the surface layer portion of the semiconductor layer (6). The internal parasitic capacitance formation portion (50, 450, 550) forms the internal parasitic capacitance (C1, C2, C3, C4, CT) between the facing portion (7a) and the main surface (3) or the extended surface (EP). Then, the first parasitic capacitance (CP1) connected in series to the internal parasitic capacitance (C1, C2, C3, C4, CT) is formed between the first pad (9) and the upper portion (230). This makes it possible to reduce the parasitic capacitance around the first pad (9) (the parasitic capacitance between the first pad and the facing portion) as compared with a case where the internal parasitic capacitance formation portion (50, 450, 550) is not formed in the surface layer portion of the semiconductor layer (6).

### [Supplementary Note A-2]

The semiconductor device (1, 201, 301, 501) of Supplementary Note A-1, wherein the internal parasitic capacitance formation portion (50, 450, 550) has a laminated structure (LS1, LS2) of a first diffusion layer (51, 551) of the second conductivity type formed on the surface layer portion of the semiconductor layer (6) so as to face the first pad (9) with the insulating layer (23) interposed therebetween and a second diffusion layer (52, 552) of the first conductivity type formed on a surface layer portion of the first diffusion layer (51, 551), and includes a laminated parasitic capacitance formation portion (50, 550) that forms a laminated parasitic capacitance (C1, C2, C3, C4) between the semiconductor layer (6) and a surface of the laminated structure (LS1, LS2).

According to this configuration, the laminated structure (LS1, LS2) including the first diffusion layer (51, 551) and the second diffusion layer (52, 552) is formed on the surface layer portion of the semiconductor layer (6). A laminated parasitic capacitance (first laminated parasitic capacitance (CL1)) is formed between the second diffusion layer (52, 552) of the first conductivity type and the first diffusion layer (51, 551) of the second conductivity type, and a laminated parasitic capacitance (second laminated parasitic capacitance (CL2)) is formed between the first diffusion layer 51 of the second conductivity type and the semiconductor layer (6) of the first conductivity type. Then, a first parasitic capacitance (CP1) connected in series to these laminated parasitic capacitances (C1, C2, C3, C4) is formed between the first pad (9) and the upper portion (230). This makes it possible to reduce the parasitic capacitance around the first pad (9) (the parasitic capacitance in the portion between the first pad and the facing portion) as compared with a case where the laminated structure (LS1, LS2) is not formed on the surface layer portion of the semiconductor layer (6).

### [Supplementary Note A-3]

The semiconductor device (1, 201, 301, 501) of Supplementary Note A-2, wherein the first diffusion layer (51, 551) is formed on the main surface (3).

### [Supplementary Note A-4]

The semiconductor device (1, 201, 301, 501) of Supplementary Note A-2 or A-3, wherein a depth (D₅) of a bottom portion (52a, 552a) of the second diffusion layer (52, 552) is less than a depth (D₇) of a bottom portion (51a, 551a) of the first diffusion layer (51, 551).

### [Supplementary Note A-5]

The semiconductor device (1, 201, 301, 501) of any one of Supplementary Notes A-2 to A-4, wherein the depth (D₇) of a bottom portion (51a, 551a) of the first diffusion layer (51, 551) is equal to a depth (D₁) of a bottom portion (17a) of the first diffusion region (17).

### [Supplementary Note A-6]

The semiconductor device (1, 201, 301, 501) of any one of Supplementary Notes A-2 to A-5, wherein the depth (D₅) of a bottom portion (52a, 552a) of the second diffusion layer (52, 552) is less than the depth (D₁) of a bottom portion (17a) of the first diffusion region (17).

### [Supplementary Note A-7]

The semiconductor device (1, 201, 301, 501) of any one of Supplementary Notes A-2 to A-6, further including an isolation portion (202, 302) formed between the first diffusion region (17) and the first diffusion layer (51, 551) and isolating the first diffusion region (17) from the first diffusion layer (51, 551).

### [Supplementary Note A-8]

The semiconductor device (1, 201, 301, 401, 501) of Supplementary Note A-7, wherein the isolation portion (202, 302) includes a high concentration region (203) of the first conductivity type having a higher first conductivity type impurity concentration than the semiconductor layer (6).

### [Supplementary Note A-9]

The semiconductor device (1, 201, 301, 501) of Supplementary Note A-8, wherein the first conductivity type impurity concentration of the high concentration region (203) is higher than a first conductivity type impurity concentration of the second diffusion region (20).

### [Supplementary Note A-10]

The semiconductor device (1, 201, 301, 501) of Supplementary Note A-7, wherein the isolation portion includes an insulating trench structure (303) including an insulating trench (304) formed in the surface layer portion of the semiconductor layer (6) and an insulator (305) buried in the insulating trench (304).

### [Supplementary Note A-11]

The semiconductor device (1, 201, 301, 501) of Supplementary Note A-10, wherein a depth (D₁₀) of the insulating trench structure (303) is greater than the depth (D₇) of the bottom portion (51a, 551a) of the first diffusion layer (51, 551).

### [Supplementary Note A-12]

The semiconductor device (1, 201, 301, 501) of any one of Supplementary Notes A-2 to A-11, wherein the laminated structure (LS1, LS2) further includes a third diffusion layer (53) of the second conductivity type formed on a surface layer portion of the second diffusion layer (52, 552).

### [Supplementary Note A-13]

The semiconductor device (1, 201, 301, 501) of any one of Supplementary Notes A-2 to A-12, wherein the first pad (9) includes an electrode surface (38) on which a connector (W) is capable of being disposed, and the laminated parasitic capacitance formation portion (50, 550) overlaps the electrode surface (38) via the insulating layer (23) in a plan view.

### [Supplementary Note A-14]

The semiconductor device (1, 201, 301, 501) of any one of Supplementary Notes A-1 to A-13, wherein the semiconductor layer (6) is a semiconductor substrate (7).

### [Supplementary Note A-15]

A semiconductor device (1, 201, 301, 501) including:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) so as to cover the first diffusion region (17) and the second diffusion region (20);
a first pad (9) disposed on the insulating layer (23) and electrically connected to the first diffusion region (17); and
a laminated parasitic capacitance formation portion (50, 550) having a laminated structure (LS1, LS2) of a first diffusion layer (51, 551) of the second conductivity type formed in a surface layer portion of the semiconductor layer (6) so as to face the first pad (9) with the insulating layer (23) interposed therebetween and a second diffusion layer (52, 552) of the first conductivity type formed in a surface layer portion of the first diffusion layer (51, 551), and forming a laminated parasitic capacitance (C1, C2, C3, C4) between the semiconductor layer (6) and a surface of the laminated structure (LS1, LS2),
wherein the first pad (9) forms a second parasitic capacitance (CP1, CP2) connected in series to the laminated parasitic capacitance (C1, C2, C3, C4) between the first pad (9) and the insulating layer (23).

The first pad (9) is at the same potential as the first diffusion region (17) of the second conductivity type. Therefore, a parasitic capacitance is formed between the first pad (9) and the semiconductor layer (6) of the first conductivity type.

According to this configuration, the laminated structure (LS1, LS2) including the first diffusion layer (51, 551) and the second diffusion layer (52, 552) is formed on the surface layer portion of the semiconductor layer (6). A laminated parasitic capacitance (first laminated parasitic capacitance (CL1)) is formed between the second diffusion layer (52, 552) of the first conductivity type and the first diffusion layer (51, 551) of the second conductivity type, and a laminated parasitic capacitance (second laminated parasitic capacitance (CL2)) is formed between the first diffusion layer 51 of the second conductivity type and the semiconductor layer (6) of the first conductivity type. Then, the second parasitic capacitance connected in series to the laminated parasitic capacitance (C1, C2, C3, C4) is formed between the first pad (9) and the insulating layer (23). This makes it possible to reduce the parasitic capacitance around the first pad (9) (the parasitic capacitance in the portion between the first pad and the facing portion) as compared with a case where the laminated structure (LS1, LS2) is not formed in the surface layer portion of the semiconductor layer (6).

### [Supplementary Note B-1]

A semiconductor device (401, 501) including:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) so as to cover the first diffusion region (17) and the second diffusion region (20);
a first pad (9) disposed on the insulating layer (23) and electrically connected to the first diffusion region (17); and
an internal parasitic capacitance formation portion (450, 550) formed in a surface layer portion of the semiconductor layer (6) and forming an internal parasitic capacitance (C1, C2, C3, C4, CT) between a facing portion (7a) in the semiconductor layer (6) that faces the first pad (9) with the insulating layer (23) interposed therebetween and the main surface (3) or an extended surface (EP) flush with the main surface (3),
wherein the internal parasitic capacitance formation portion (450, 550) includes a trench parasitic capacitance formation portion (450) including a first trench (451) formed on the main surface (3) and an intra-trench insulating layer (231) of the insulating layer (23) buried in the first trench (451) and forming a trench parasitic capacitance (CT) between the extended surface (EP) in the first trench (451) and the facing portion (7a) formed on a bottom surface (452) of the first trench (451), and
wherein the first pad (9) forms a first parasitic capacitance (CP1) connected in series to the trench parasitic capacitance (CT) between the first pad (9) and an upper portion (230) of the insulating layer (23) formed over the main surface (3) or the extended surface (EP).

According to this configuration, the trench parasitic capacitance formation portion (450) is formed in the surface layer portion of the semiconductor layer (6). The trench parasitic capacitance formation portion (450) forms the trench parasitic capacitance (CT) between the facing portion (7a) and the main surface (3) or the extended surface (EP). Then, the first parasitic capacitance (CP1) connected in series to the trench parasitic capacitance (CT) is formed between the first pad (9) and the upper portion (230). This makes it possible to reduce the parasitic capacitance around the first pad (9) (the parasitic capacitance in the portion between the first pad and the facing portion) as compared with a case where the trench parasitic capacitance formation portion (450) is not formed in the surface layer portion of the semiconductor layer (6).

### [Supplementary Note B-2]

The semiconductor device (401, 501) of Supplementary Note B-1, wherein the bottom surface (452) of the first trench (451) is a flat surface parallel to the main surface (3).

### [Supplementary Note B-3]

The semiconductor device (401, 501) of Supplementary Note B-1 or B-2, wherein a depth (DT) of the bottom surface (452) of the first trench (451) is greater than a depth (D₁) of a bottom portion (17a) of the first diffusion region (17).

### [Supplementary Note B-4]

The semiconductor device (401, 501) of any one of Supplementary Notes B-1 to B-3, wherein the first pad (9) has an electrode surface (38) on which a connector (W) is capable of being disposed, and the trench parasitic capacitance formation portion (450) overlaps the electrode surface (38) via the insulating layer (23) in a plan view.

### [Supplementary Note B-5]

The semiconductor device (501) of any one of Supplementary Notes B-1 to B-4, wherein the internal parasitic capacitance formation portion (450, 550) has a laminated structure (LS2) of a first diffusion layer (51, 551) of the second conductivity type formed in the surface layer portion of the semiconductor layer (6) so as to face the first pad (9) with the insulating layer (23) interposed therebetween and a second diffusion layer (52, 552) of the first conductivity type formed in a surface layer portion of the first diffusion layer (51, 551), and further includes a laminated parasitic capacitance formation portion (550) that forms a laminated parasitic capacitance (C1, C2, C3, C4) between the semiconductor layer (6) and a surface of the laminated structure (LS2).

### [Supplementary Note B-6]

The semiconductor device (501) of Supplementary Note B-5, wherein the depth (D₅) of a bottom portion (52a, 552a) of the second diffusion layer (52, 552) is less than a depth (D₇) of a bottom portion (51a, 551a) of the first diffusion layer (51, 551).

### [Supplementary Note B-7]

The semiconductor device (501) of Supplementary Note B-5 or B-6, wherein the depth (D₇) of the bottom portion (51a, 551a) of the first diffusion layer (51, 551) is equal to the depth (D₁) of the bottom portion (17a) of the first diffusion region (17).

### [Supplementary Note B-8]

The semiconductor device (501) of any one of Supplementary Notes B-5 to B-7, wherein the depth (D₅) of the bottom portion (52a, 552a) of the second diffusion layer (52, 552) is less than the depth (D₁) of the bottom portion (17a) of the first diffusion region (17).

### [Supplementary Note B-9]

The semiconductor device (501) of any one of Supplementary Notes B-5 to B-8, further including an isolation portion (202, 302) formed between the first diffusion layer (51, 551) and a periphery of the bottom surface (452) of the first trench (451) and isolating the first diffusion region (17) from the first diffusion layer (51, 551).

### [Supplementary Note B-10]

The semiconductor device (501) of Supplementary Note B-9, wherein the isolation portion (202, 302) includes a high concentration region (203) of the first conductivity type having a higher first conductivity type impurity concentration than the semiconductor layer (6).

### [Supplementary Note B-11]

The semiconductor device (501) of Supplementary Note B-10, wherein the first conductivity type impurity concentration of the high concentration region (203) is higher than a first conductivity type impurity concentration of the second diffusion region (20).

### [Supplementary Note B-12]

The semiconductor device (501) of Supplementary Note B-9, wherein the isolation portion includes an insulating trench structure (303) including an insulating trench (304) formed in the bottom surface (452) of the first trench (451) and an insulator (305) buried in the insulating trench (304).

### [Supplementary Note B-13]

The semiconductor device (501) of Supplementary Note B-12, wherein a depth (D₁₀) of the insulating trench structure (303) is greater than the depth (D₇) of the bottom portion (51a, 551a) of the first diffusion layer (51, 551).

### [Supplementary Note B-14]

The semiconductor device (401, 501) of any one of Supplementary Notes B-1 to B-13, wherein the semiconductor layer (6) is a semiconductor substrate (7).

### [Supplementary Note B-15]

A semiconductor device (401, 501) including:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) so as to cover the first diffusion region (17) and the second diffusion region (20);
a first pad (9) disposed on the insulating layer (23) and electrically connected to the first diffusion region (17); and
a first trench (451) formed on the main surface (3) so as to face the first pad with the insulating layer interposed therebetween,
wherein a portion (231) of the insulating layer is buried in the first trench (451), and
wherein the first pad (9) forms a third parasitic capacitance (CP2) with a facing region (7a) formed in a bottom surface (452) of the first trench (451) so as to face the first pad (9) with the insulating layer (23) interposed therebetween.

According to this configuration, a trench parasitic capacitance formation portion (450) is formed in a surface layer portion of the semiconductor layer (6). As compared with a case where the first trench (451) is not formed in the first main surface (3), a distance between the first pad (9) and the facing portion (7a) can be kept large. Since the third parasitic capacitance (CP2) is inversely proportional to a distance between electrodes, a parasitic capacitance around the first pad (9) can be reduced by keeping the distance between the first pad (9) and the facing portion (7a) large.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor layer of a first conductivity type having a main surface;
a first diffusion region of a second conductivity type formed in a surface layer portion of the main surface;
a second diffusion region of the first conductivity type formed in the surface layer portion of the main surface;
an insulating layer formed on the main surface so as to cover the first diffusion region and the second diffusion region;
a first pad disposed on the insulating layer and electrically connected to the first diffusion region; and
an internal parasitic capacitance formation portion formed in a surface layer portion of the semiconductor layer and forming an internal parasitic capacitance between a facing portion in the semiconductor layer that faces the first pad with the insulating layer interposed therebetween and the main surface or an extended surface flush with the main surface,
wherein the internal parasitic capacitance formation portion includes a trench parasitic capacitance formation portion including a first trench formed on the main surface and an intra-trench portion of the insulating layer buried in the first trench and forming a trench parasitic capacitance between the extended surface in the first trench and the facing portion formed on a bottom surface of the first trench, and
wherein the first pad forms a first parasitic capacitance connected in series to the trench parasitic capacitance between the first pad and an upper portion of the insulating layer formed over the main surface or the extended surface.

2. The semiconductor device of claim 1, wherein the bottom surface of the first trench is a flat surface parallel to the main surface.

3. The semiconductor device of claim 1, wherein a depth of the bottom surface of the first trench is greater than a depth of a bottom portion of the first diffusion region.

4. The semiconductor device of claim 1, wherein the first pad has an electrode surface on which a connector is capable of being disposed, and the trench parasitic capacitance formation portion overlaps the electrode surface via the insulating layer in a plan view.

5. The semiconductor device of claim 1, wherein the internal parasitic capacitance formation portion has a laminated structure of a first diffusion layer of the second conductivity type formed in the surface layer portion of the semiconductor layer so as to face the first pad with the insulating layer interposed therebetween and a second diffusion layer of the first conductivity type formed in a surface layer portion of the first diffusion layer, and further includes a laminated parasitic capacitance formation portion that forms a laminated parasitic capacitance between the semiconductor layer and a surface of the laminated structure.

6. The semiconductor device of claim 5, wherein a depth of a bottom portion of the second diffusion layer is less than a depth of a bottom portion of the first diffusion layer.

7. The semiconductor device of claim 5, wherein a depth of a bottom portion of the first diffusion layer is equal to a depth of a bottom portion of the first diffusion region.

8. The semiconductor device of claim 5, wherein a depth of a bottom portion of the second diffusion layer is less than a depth of a bottom portion of the first diffusion region.

9. The semiconductor device of claim 5, further comprising an isolation portion formed between the first diffusion layer and a periphery of the bottom surface of the first trench and isolating the first diffusion region from the first diffusion layer.

10. The semiconductor device of claim 9, wherein the isolation portion includes a high concentration region of the first conductivity type having a higher first conductivity type impurity concentration than the semiconductor layer.

11. The semiconductor device of claim 10, wherein the first conductivity type impurity concentration of the high concentration region is higher than a first conductivity type impurity concentration of the second diffusion region.

12. The semiconductor device of claim 9, wherein the isolation portion includes an insulating trench structure including an insulating trench formed in the bottom surface of the first trench and an insulator buried in the insulating trench.

13. The semiconductor device of claim 12, wherein a depth of a bottom portion of the insulating trench structure is greater than a depth of a bottom portion of the first diffusion layer.

14. The semiconductor device of claim 1, wherein the semiconductor layer is a semiconductor substrate.

15. A semiconductor device comprising:
a semiconductor layer of a first conductivity type having a main surface;
a first diffusion region of a second conductivity type formed in a surface layer portion of the main surface;
a second diffusion region of the first conductivity type formed in the surface layer portion of the main surface;
an insulating layer formed on the main surface so as to cover the first diffusion region and the second diffusion region;
a first pad disposed on the insulating layer and electrically connected to the first diffusion region; and
a first trench formed on the main surface,
wherein a portion of the insulating layer is buried in the first trench, and
wherein the first pad forms a parasitic capacitance with a facing region formed in a bottom surface of the first trench so as to face the first pad with the insulating layer interposed therebetween.
